(19) United States
(12) Patent Application Publication
(10) Pub. No.: US 2026/0342039 A1
(43) Pub. Date: Oct. 29, 2026

(54) FIRST MODULE AND PLURALITY OF MODULES INCLUDING FIRST MODULE

(71) Applicant: NICHIA CORPORATION, Anan-shi (JP)

(72) Inventors: Hiroshi SHIRAISHI, Anan-shi (JP); Takashi MIYOSHI, Anan-shi (JP)

(21) Appl. No.: 19/657,633

(22) Filed: Apr. 24, 2026

(30) Foreign Application Priority Data
Apr. 25, 2025 (JP) 2025-073418

(51) Int. Cl. H01S 5/02315; H01S 5/042; H01S 5/40

(52) U.S. Cl. CPC H01S 5/02315; H01S 5/04256; H01S 5/4018

(57) ABSTRACT

A light-emitting module includes: a first device including a first base and a power-consuming component; and a first wiring substrate provided with a first electrode portion and a second electrode portion, the first wiring substrate including a plurality of wiring members the first electrode portion is electrically connected to the power-consuming component on a first electrode side of the power-consuming component, the second electrode portion is electrically connected to the power-consuming component on a second electrode side of the power-consuming component, the second conductive portion includes a first conductive region and a second conductive region that are not electrically connected to each other in a state of the first base, the first wiring region and the second wiring region of the wiring members form a current path, and the wiring member forming the current path between the first conductive region and the second wiring region is not in contact with the second conductive region.

### CROSS-REFERENCE TO RELATED APPLICATION

This application claims priority to Japanese Patent Application No. 2025-073418, filed on Apr. 25, 2025, the disclosure of which is hereby incorporated by reference in its entirety.

### TECHNICAL FIELD

The present disclosure relates to a first module and a plurality of modules including the first module.

### BACKGROUND

Japanese Patent Publication No. 2021-197414 discloses a substrate module in which a power-receiving device is disposed on a substrate provided with a plurality of wiring regions. In this substrate module, electric power is supplied to a power-receiving device such as a light-emitting device, and the power-receiving device consumes the electric power to provide a desired function such as light emission.

### SUMMARY

The present disclosure discloses a problem of improving performance in exhibiting desired functions in the technical field according to the present disclosure.

Alternatively, the present disclosure discloses a problem of providing a module suitable for a specific usage mode to a device having selectivity in usage modes in the technical field according to the present disclosure, instead of the above-described problem.

Alternatively, the present disclosure discloses a problem of enhancing mounting accuracy of a module in the technical field according to the present disclosure, instead of the above-described problems.

Alternatively, the present disclosure discloses a problem of suppressing an increase in size of a module in the technical field according to the present disclosure, instead of the above-described problems.

In addition, based on technical common knowledge in the technical field according to the present disclosure, there are not only the above-described problems, but also problems that can be recognized from the description in the specification of the present application.

In addition, based on technical common knowledge in the technical field according to the present disclosure, not only the above-described problems, but also obtaining an effect that can be understood as being achieved by technical matters described in the specification of the present application may be regarded as a problem.

The present disclosure solves at least one of the problems described above.

A first module disclosed in an embodiment includes: a first device including a first base having an upper surface, a lower surface, and a first conductive portion and a second conductive portion that are provided on the lower surface, and a first power-consuming component disposed on the first base and configured to consume electric power supplied through the first base; and a first wiring substrate provided with a first electrode portion and a second electrode portion for supplying electric power to the first power-consuming component, the first wiring substrate including a plurality of wiring members for forming a first current path from the first electrode portion to the second electrode portion or from the second electrode portion to the first electrode portion through the first device, in which the first power-consuming component includes a first electrode and a second electrode, the first electrode portion is electrically connected to the first power-consuming component on a first electrode side of the first power-consuming component, the second electrode portion is electrically connected to the first power-consuming component on a second electrode side of the first power-consuming component, the first conductive portion and the second conductive portion of the first device are bonded to the first wiring substrate in a first bonding region of the first wiring substrate, the second conductive portion includes a first conductive region and a second conductive region that are not electrically connected to each other in a state of the first base, the plurality of wiring members of the first wiring substrate include a first wiring region connected to the first conductive region of the second conductive portion in the first bonding region, and a second wiring region opposed to the first wiring region with the second conductive region of the second conductive portion interposed between the first wiring region and the second wiring region in a top view, the second wiring region of the first wiring substrate is located outside the first bonding region, the first wiring region and the second wiring region form a part of the first current path, and the wiring member forming the first current path between the first conductive region of the second conductive portion and the second wiring region is not in contact with the second conductive region of the second conductive portion.

A plurality of modules disclosed in the embodiment include, in addition to the first module, a second module including a third device including a third base having an upper surface, a lower surface, and a first conductive portion and a second conductive portion that are provided on the lower surface, and a third power-consuming component disposed on the upper surface of the third base and configured to consume electric power supplied through the third base, and a second wiring substrate provided with a first electrode portion and a second electrode portion for supplying electric power to the third power-consuming component, the second wiring substrate including a plurality of wiring members for forming a second current path from the first electrode portion to the second electrode portion or from the second electrode portion to the first electrode portion through the third device, in which the first base and the third base are identical bases, the first conductive portion and the second conductive portion of the third device are bonded to the second wiring substrate in a second bonding region of the second wiring substrate, the first conductive portion of the third base includes a first conductive region and a second conductive region that are not electrically connected to each other, the second conductive portion of the third base includes a first conductive region and a second conductive region that are not electrically connected to each other, the plurality of wiring members of the second wiring substrate include a first wiring member connected to the first conductive region of the first conductive portion in the second bonding region, and a second wiring member connected to the second conductive region of the first conductive portion in the second bonding region, and formation of the second current path does not need the second conductive portion of the third device.

### BRIEF DESCRIPTION OF DRAWINGS

FIG. 1 is a perspective view of a light-emitting module according to a first embodiment.

FIG. 2 is a top view of the light-emitting module according to the first embodiment.

FIG. 3 is a schematic top view of a wiring substrate according to the first embodiment.

FIG. 4 is a schematic cross-sectional view of the wiring substrate taken along line IV-IV in FIG. 3.

FIG. 5A is a schematic perspective view of a light-emitting device according to each embodiment.

FIG. 5B is a schematic top view of the light-emitting device according to each embodiment.

FIG. 5C is a schematic side view of the light-emitting device according to each embodiment.

FIG. 5D is a schematic cross-sectional view of the light-emitting device according to each embodiment taken along line VD-VD in FIG. 5B.

FIG. 5E is a schematic perspective view of the inside of a package of the light-emitting device according to each embodiment.

FIG. 5F is a schematic top view of the inside of the package of the light-emitting device according to each embodiment.

FIG. 5G is a schematic perspective view of the package.

FIG. 5H is a schematic cross-sectional view of the package taken along line VD-VD in FIG. 5B.

FIG. 5I is a schematic top view of a base.

FIG. 5J is a schematic bottom view of the base.

FIG. 5K is a schematic cross-sectional view of the base taken along line VD-VD in FIG. 5B.

FIG. 5L is a schematic top view of a submount with another component disposed thereon.

FIG. 5M is a schematic side view of the submount with another component disposed thereon.

FIG. 6 is a schematic top view illustrating the inside of the package of the light-emitting device in the light-emitting module according to the first embodiment.

FIG. 7 is a schematic top view of the wiring substrate according to the first embodiment with an insulating portion removed.

FIG. 8 is a schematic enlarged top view for describing a connection state between the light-emitting device and the wiring substrate in the light-emitting module according to the first embodiment.

FIG. 9 is a schematic perspective view of a light-emitting module according to a second embodiment.

FIG. 10 is a schematic top view of the light-emitting module according to the second embodiment.

FIG. 11 is a schematic top view illustrating a wiring substrate according to the second embodiment.

FIG. 12 is a schematic top view illustrating the inside of a package of a light-emitting device in the light-emitting module according to the second embodiment.

FIG. 13 is a schematic top view of the wiring substrate according to the second embodiment with an insulating portion removed.

FIG. 14 is a schematic enlarged top view for describing a connection state between the light-emitting device and the wiring substrate in the light-emitting module according to the second embodiment.

FIG. 15 is a schematic perspective view of a second light-emitting module according to a third embodiment.

FIG. 16 is a schematic top view of the second light-emitting module according to the third embodiment.

FIG. 17 is a schematic top view of a wiring substrate of the second light-emitting module according to the third embodiment.

FIG. 18 is a schematic top view illustrating the inside of a package of a light-emitting device in the second light-emitting module according to the third embodiment.

FIG. 19 is a schematic top view of the wiring substrate according to the third embodiment with an insulating portion removed.

### DETAILED DESCRIPTION

In the present specification or the claims, polygons such as triangles and quadrangles, including shapes in which the corners of the polygon are rounded, beveled, chamfered, or coved, are referred to as polygons. Not only a shape in which a corner (an end of a side) is processed, but also a shape in which an intermediate portion of a side is processed is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies to a case of treating each side forming the shapes. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present disclosure.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

An embodiment for implementing the present disclosure will be described below. A specific embodiment for implementing the present disclosure will be described below with reference to the drawings. An embodiment for implementing the present disclosure is not limited to the specific embodiment. That is, the embodiment illustrated by the drawings is not the only form in which the present disclosure is implemented. Sizes and positional relationships of members illustrated in each of the drawings may sometimes be exaggerated in order to facilitate understanding.

The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the drawings, when a form that is directly “on” or “covering” is disclosed, the configuration that is directly disposed on, or that directly covers, is disclosed as an exemplary embodiment.

### First Embodiment

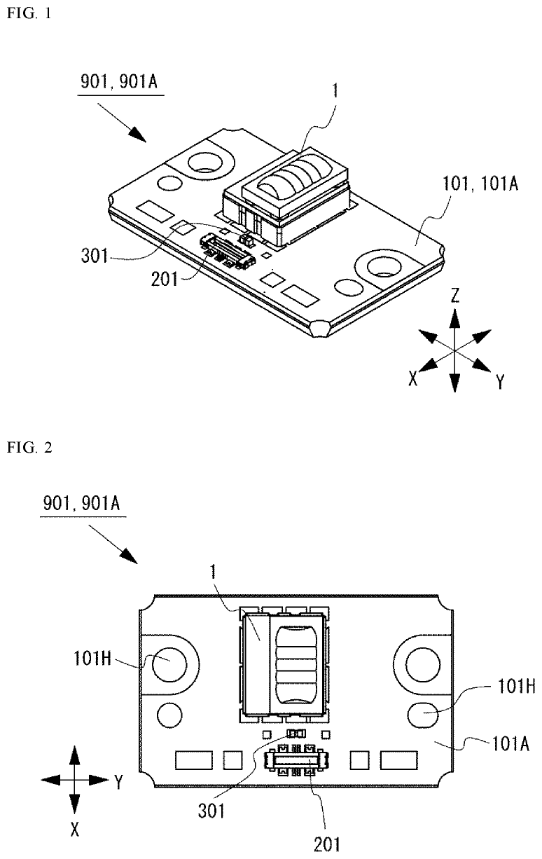

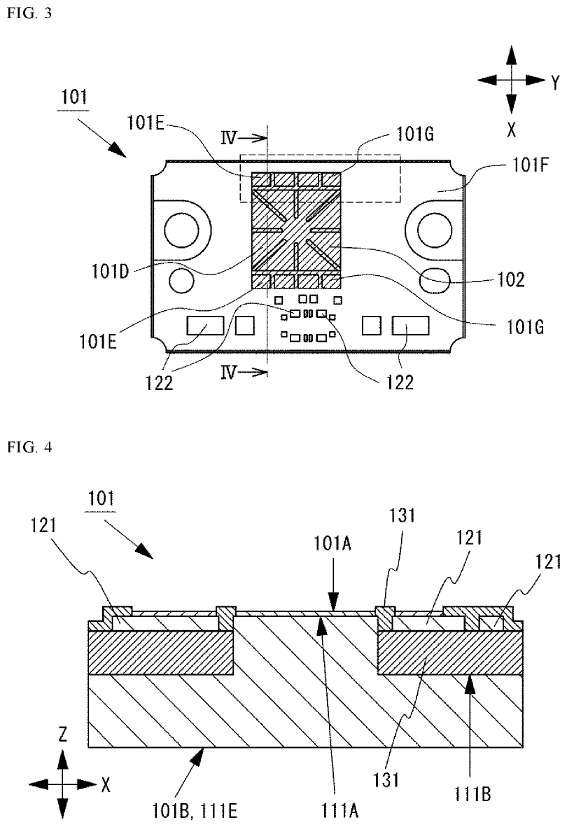

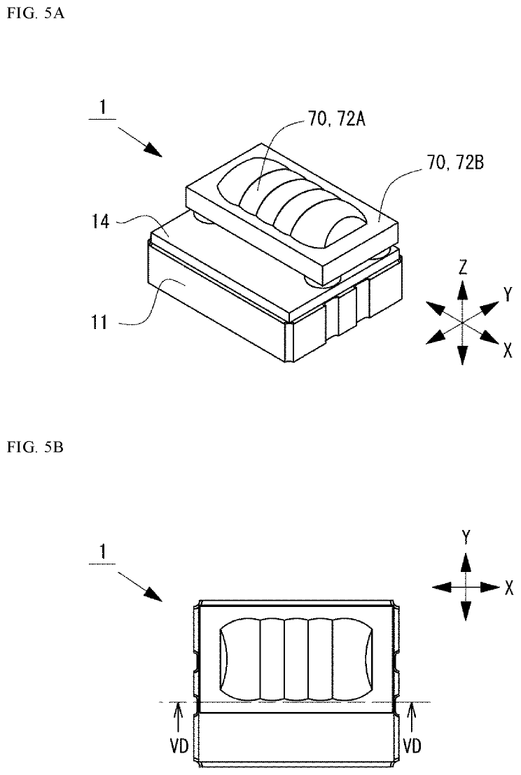

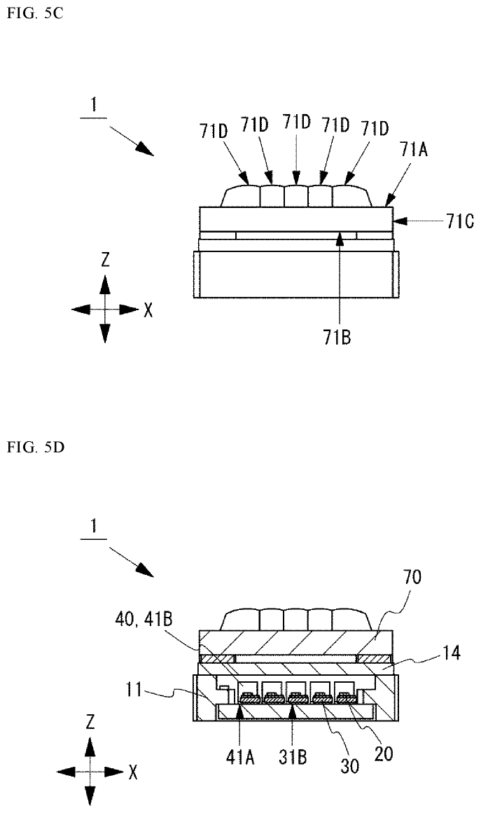

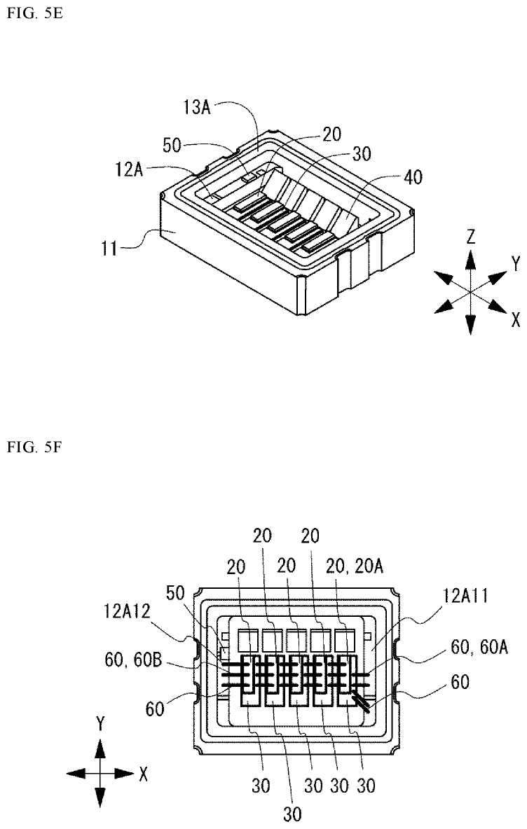

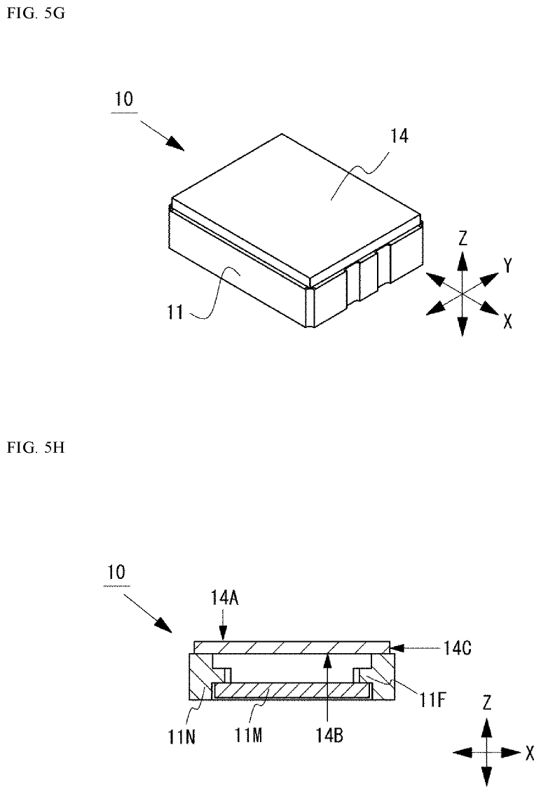

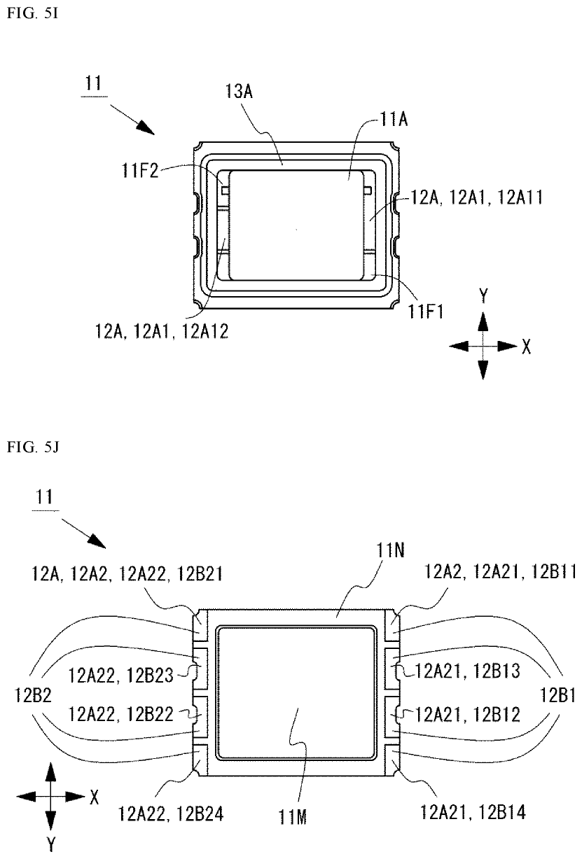

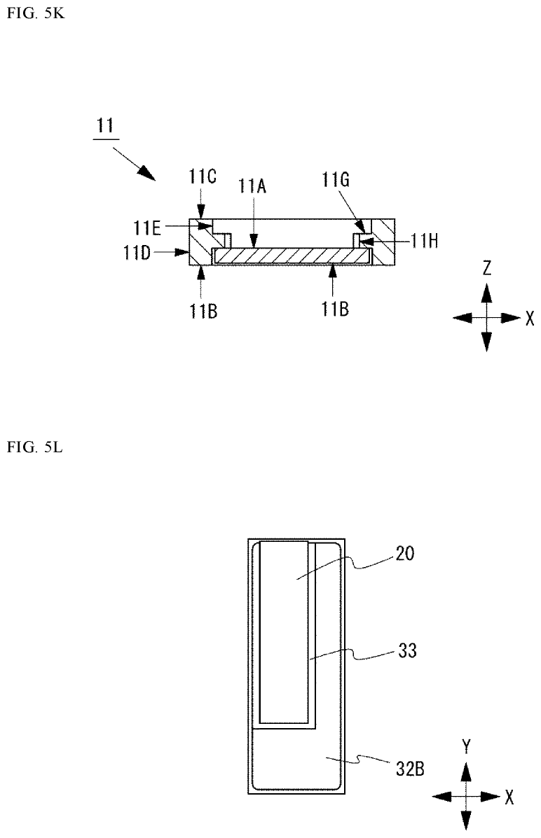

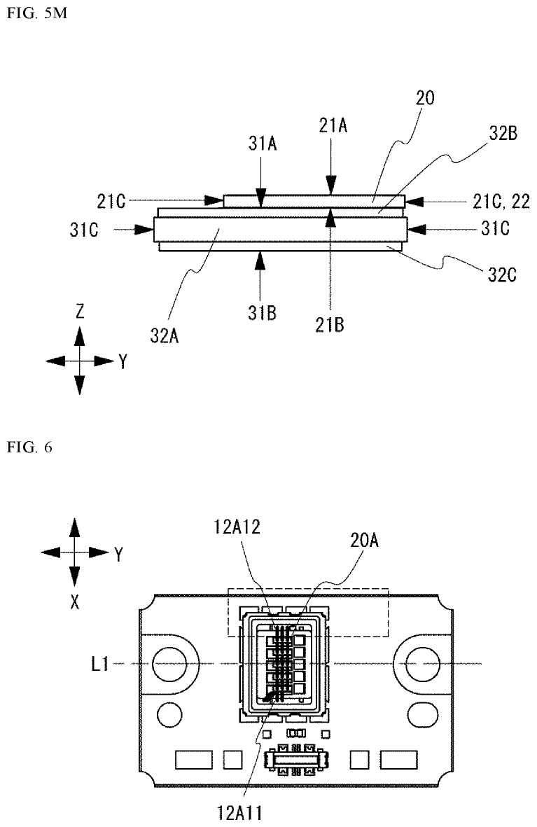

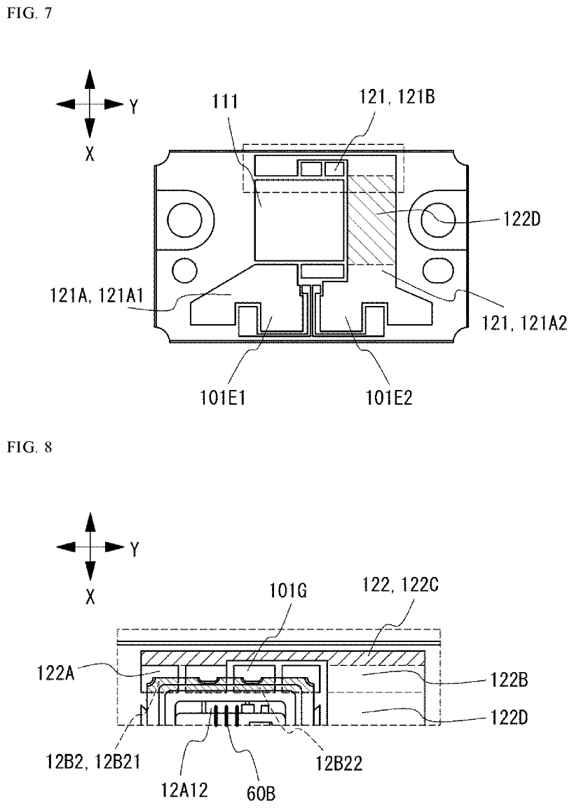

A light-emitting module 901 according to a first embodiment will be described. FIGS. 1 to 8 are schematic drawings for describing an exemplary embodiment of a light-emitting module 901. FIG. 1 is a perspective view of the light-emitting module 901. FIG. 2 is a schematic top view of the light-emitting module 901. FIG. 3 is a schematic top view of a wiring substrate 101. In FIG. 3, hatching is added to a bonding region 102. In addition, the broken-line rectangle illustrates an enlarged portion in the enlarged top view of FIG. 8. FIG. 4 is a schematic cross-sectional view of the wiring substrate 101 taken along line IV-IV in FIG. 3. FIG. 5A is a schematic perspective view of a light-emitting device 1. FIG. 5B is a schematic top view of the light-emitting device 1. FIG. 5C is a schematic side view of the light-emitting device 1. FIG. 5D is a schematic cross-sectional view of the light-emitting device 1 taken along line VD-VD in FIG. 5B. FIG. 5E is a schematic perspective view of the inside of a package 10 of the light-emitting device 1. In FIG. 5E, wirings 60 are omitted. FIG. 5F is a schematic top view of the inside of the package 10 of the light-emitting device 1. FIG. 5G is a schematic perspective view of the package 10. FIG. 5H is a schematic cross-sectional view of the package 10 taken along line VD-VD in FIG. 5B. FIG. 5I is a schematic top view of a base 11. FIG. 5J is a schematic bottom view of the base 11. FIG. 5K is a schematic cross-sectional view of the base 11 taken along line VD-VD of FIG. 5B. FIG. 5L is a schematic top view of a submount 30 with other components disposed thereon. FIG. 5M is a schematic side view of the submount 30 with other components disposed thereon. FIG. 6 is a schematic top view illustrating the inside of the package 10 of the light-emitting device 1 in the light-emitting module 901. FIG. 7 is a schematic top view of the wiring substrate 101 with an insulating portion 101F removed. In FIG. 7, hatching is added to a bypass region 122D. FIG. 8 is a schematic enlarged top view for describing a connection state between the light-emitting device 1 and the wiring substrate 101 in the light-emitting module 901. FIG. 8 is an enlarged view of a region surrounded by a broken-line rectangle in FIGS. 3, 6, and 7. In addition, for clearly illustrating the connection state, some components are appropriately made transparent or omitted.

The light-emitting module 901 includes a plurality of components. The plurality of components included in the light-emitting module 901 include one or more light-emitting devices 1, the wiring substrate 101, a connector 201, and a thermistor 301.

The light-emitting module 901 may also include a component other than these components. For example, the light-emitting module 901 may include a light-emitting device different from the light-emitting device 1. The light-emitting module 901 need not include some of the plurality of components described above.

The light-emitting device 1 includes a plurality of components. The plurality of components include the package 10, one or more semiconductor laser elements 20, one or more submounts 30, one or more reflective members 40, one or more protective elements 50, a plurality of wirings 60, and an optical member 70.

The light-emitting device 1 may include a component other than the components described above. For example, the light-emitting device 1 may further include a semiconductor laser element different from the one or more semiconductor laser elements 20. The light-emitting device 1 need not include some of the components described above.

Firstly, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or an airtight state.

The outer edge shape of the package 10 in a top view is rectangular. This rectangular shape can be a rectangular shape with long sides and short sides. In the package 10 illustrated by the drawing(s), the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. A first upper surface 11A of the package 10 is a part of the region defining the internal space. In addition, inner lateral surfaces 11E and a lower surface 14B of the package 10 are a part of the region defining the internal space.

The base 11 includes the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F includes an upper surface 11G and a lateral surface 11H meeting the upper surface 11G and extending downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. The one or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The term “perpendicular” as used here allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on the short sides of the inner frame of the second upper surface 11C.

The base 11 includes a base portion 11M and a frame portion 11N. The base portion 11M and the frame portion 11N may be members formed of mutually different materials. The base 11 can include a base member corresponding to the base portion 11M and a frame member corresponding to the frame portion 11N.

The base portion 11M has the first upper surface 11A. The frame portion 11N has the second upper surface 11C. The frame portion 11N has the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The plurality of wiring portions 12A include one or more inner wiring portions 12A1 disposed in the internal space of the package 10, and one or more outer wiring portions 12A2 provided on an outer surface of the package 10.

One or each of the inner wiring portions 12A1 is provided on the upper surface 11G of the step portion 11F. The base 11 includes the one or more inner wiring portions 12A1 provided on the upper surface 11G of the first step portion 11F1. The base 11 includes the one or more inner wiring portions 12A1 provided on the upper surface 11G of the second step portion 11F2.

The one or more inner wiring portions 12A1 may include a plurality of inner wiring portions 12A1 including one or more first inner wiring portions 12A11 provided on the first lateral surface side, and one or more second inner wiring portions 12A12 provided on the second lateral surface side. Here, the first lateral surface and the second lateral surface are either the outer lateral surface 11D or the inner lateral surface 11E. The first lateral surface and the second lateral surface are in a relationship in which one lateral surface faces the other lateral surface, or one lateral surface is opposite the other lateral surface.

In the base 11 illustrated by the drawing(s), the one or more inner wiring portions 12A1 provided on the upper surface 11G of the first step portion 11F1 may be referred to as the first inner wiring portion 12A11, and the one or more inner wiring portions 12A1 provided on the upper surface 11G of the second step portion 11F2 may be referred to as the second inner wiring portion 12A12.

The one or more first inner wiring portions 12A11 may include a plurality of first inner wiring portions 12A11 that are not electrically connected to each other. The one or more second inner wiring portions 12A12 may include a plurality of second inner wiring portions 12A12 that are not electrically connected to each other. The plurality of first inner wiring portions 12A11 are arranged next to each other in a direction along the first lateral surface. The plurality of second inner wiring portions 12A12 are arranged next to each other in a direction along the second lateral surface.

One or each of the outer wiring portions 12A2 is provided on the lower surface 11B of the package 10. The one or each of the outer wiring portions 12A2 is provided on the lower surface of the frame portion 11N. The outer wiring portion 12A2 may be provided on an outer surface different from the lower surface 11B of the package 10.

The one or more outer wiring portions 12A2 may include a plurality of outer wiring portions 12A2 including one or more first outer wiring portions 12A21 provided on the first lateral surface side, and one or more second outer wiring portions 12A22 provided on the second lateral surface side.

The one or more first outer wiring portions 12A21 may include a plurality of the first outer wiring portions 12A21 that are not electrically connected to each other. The one or more second outer wiring portions 12A22 may include a plurality of the second outer wiring portions 12A22 that are not electrically connected to each other. The plurality of first outer wiring portions 12A21 are arranged next to each other in a direction along the first lateral surface. The plurality of second outer wiring portions 12A22 are arranged next to each other in a direction along the second lateral surface.

In the base 11, the one or each of the inner wiring portions 12A1 is electrically connected to the outer wiring portion 12A2. The one or more inner wiring portions 12A1 are electrically connected to the outer wiring portions 12A2 different from each other.

The one or more first inner wiring portions 12A11 include at least one first inner wiring portion 12A11 that is electrically connected to the first outer wiring portion 12A21 and the second outer wiring portion 12A22. Here, the inner wiring portion 12A1 that is electrically connected to both the outer wiring portion 12A2 on the first lateral surface side and the outer wiring portion 12A2 on the second lateral surface side is referred to as the inner wiring portion 12A1 connected to both sides.

The one or more second inner wiring portions 12A12 include at least one second inner wiring portion 12A12 that is electrically connected to the first outer wiring portion 12A21 and the second outer wiring portion 12A22. In other words, the one or more second inner wiring portions 12A12 include the at least one second inner wiring portion 12A12 connected to both sides.

As described above, the base 11 including the inner wiring portion 12A1 connected to both sides enables appropriate selection as to which of the outer wiring portions 12A2 on the first lateral surface side and the outer wiring portions 12A2 on the second lateral surface side are used for forming a current path, and selectivity in usage modes can be provided.

With such selectivity, as a result of appropriate selection for forming the current path, only one of the outer wiring portions 12A2 on both sides may be used for forming the current path in some cases. In this case, even when the outer wiring portions 12A2 on both sides are in a state of having electrical connection, only one of the outer wiring portions 12A2 may become a state of substantially serving to form the current path. In other words, the other outer wiring portion 12A2 may become a state of not substantially serving as a wiring that constitutes a part of the current path.

Whether or not the outer wiring portion 12A2 substantially serves as the wiring that constitutes a current path depends on the actual usage mode of a device, and in any event, in the sense that at least electrical connection is established, each individual inner wiring portion 12A1 that is electrically connected to any one of the outer wiring portions 12A2 can be referred to as a conductive region. Similarly, each individual outer wiring portion 12A2 that is electrically connected to any one of the inner wiring portions 12A1 can be referred to as a conductive region.

In the plurality of the outer wiring portions 12A2, there are a combination of two of the outer wiring portions 12A2 that have electrical connection to each other, and a combination of two of the outer wiring portions 12A2 that do not have electrical connection to each other. In the plurality of first outer wiring portions 12A21, each of the first outer wiring portions 12A21 does not have electrical connection to another first outer wiring portion 12A21. In the plurality of second outer wiring portions 12A22, each of the second outer wiring portions 12A22 does not have electrical connection to another second outer wiring portion 12A22.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

Here, the main material refers to a material that accounts for the greatest proportion of a target formed product in terms of mass or volume. When a target formed product is formed of a single material, the single material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include copper, aluminum, and iron. Examples of the composite containing the metal as the main material of the base member include copper-molybdenum and copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can include one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can include one or more metal layers, for example.

The lid body 14 has an upper surface 14A and the lower surface 14B. The lid body 14 also has one or more lateral surfaces 14C. The lid body 14 is formed of a flat plate with a rectangular parallelepiped shape. The lid body 14 does not necessarily have a rectangular parallelepiped shape.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 has transmissivity to transmit light. The term “transmissivity” as used here refers to the transmittance for light incident on the lid body 14 being equal to or more than 80%. The lid body 14 may partially include a non-light-transmissive region (a region with no transmissivity).

The lid body 14 can be formed using glass as a main material, for example. The lid body 14 can also be formed using sapphire as a main material, for example.

### Semiconductor Laser Element 20

The semiconductor laser element 20 has an upper surface 21A, a lower surface 21B, and a plurality of lateral surfaces 21C. A shape of the upper surface 21A is a rectangle having long sides and short sides. An outer shape of the semiconductor laser element 20 in a top view is a rectangle having long sides and short sides. The shape of the upper surface 21A and the outer shape of the semiconductor laser element 20 in the top view are not limited thereto.

The semiconductor laser element 20 has a light-emitting surface 22 from which light is emitted. For example, the lateral surface 21C may serve as the light-emitting surface 22. The lateral surface 21C serving as the light-emitting surface 22 meets a short side of the upper surface 21A. For example, the upper surface 21A can serve as the light-emitting surface 22.

The semiconductor laser element 20 includes a first electrode and a second electrode. For example, the first electrode is an anode electrode, and the second electrode is a cathode electrode. The first electrode may be a cathode electrode and the second electrode may be an anode electrode. For example, the first electrode may be provided on the upper surface 21A, and the second electrode may be provided on the lower surface 21B.

As the semiconductor laser element 20, a single-emitter semiconductor laser element including one emitter can be employed. As the semiconductor laser element 20, a multi-emitter semiconductor laser element including a plurality of emitters can be employed.

As the semiconductor laser element 20, for example, a semiconductor laser element that emits blue light can be employed. Also, for example, as the semiconductor laser element 20, a semiconductor laser element that emits green light can be employed. Also, for example, as the semiconductor laser element 20, a semiconductor laser element that emits red light can be employed. A semiconductor laser element that emits light of another color or light having another wavelength may be employed as the semiconductor laser element 20.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the semiconductor laser element 20 that emits blue light or the semiconductor laser element 20 that emits green light include a semiconductor laser element including a nitride semiconductor. A GaN-based semiconductor, such as GaN, InGaN, or AlGaN, can be employed as the nitride semiconductor. Examples of the semiconductor laser element 20 that emits red light include a semiconductor laser element including an InAlGaP-based semiconductor, a GaInP-based semiconductor, or a GaAs-based semiconductor such as GaAs or AlGaAs.

The semiconductor laser element 20 emits a directional laser beam. Divergent light that spreads is emitted from the light-emitting surface 22 (emission end surface) of the semiconductor laser element 20. The light emitted from the semiconductor laser element 20 forms a far-field pattern (hereinafter referred to as an “FFP”) with an elliptical shape on a plane parallel to the light-emitting surface 22. The FFP indicates a shape or a light intensity distribution of the emitted light at a position apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The shape of the FFP of the light emitted from the semiconductor laser element 20 has an elliptical shape in which a length in a layering direction is longer than that in a direction perpendicular to the layering direction on the plane parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the present specification, the term “divergence angle of light” by itself refers to a divergence angle of light at the light intensity of 1/e² of the peak light intensity.

The divergence angle of the light emitted from the semiconductor laser element 20 in the fast axis direction may be in a range from 45 degrees to less than 71 degrees. Also, the divergence angle of the light in the slow axis direction can be in a range exceeding 0 degrees and equal to or less than 13 degrees. Also, the divergence angle of the light in the fast axis direction is greater than the divergence angle of the light in the slow axis direction.

For example, the divergence angle of blue light emitted from the semiconductor laser element 20 in the fast axis direction may be in a range from 35 degrees to less than 55 degrees, and the divergence angle of the blue light in the slow axis direction may be in a range from 5 degrees to less than 16 degrees. Also, for example, the divergence angle of green light emitted from the semiconductor laser element 20 in the fast axis direction may be in a range from 30 degrees to less than 51 degrees, and the divergence angle of the green light in the slow axis direction may be in a range from 5 degrees to less than 16 degrees. Also, for example, the divergence angle of red light emitted from the semiconductor laser element 20 in the fast axis direction may be in a range from 45 degrees to less than 71 degrees, and the divergence angle of the red light in the slow axis direction may be in a range from 6 degrees to less than 16 degrees.

### Submount 30

The submount 30 has an upper surface 31A, a lower surface 31B, and one or more lateral surfaces 31C. The upper surface 31A is regarded as a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with relatively high heat dissipation (having high thermal conductivity) as the main material of the substrate 32A.

A metal such as copper or aluminum is used as the main material of the upper metal member 32B. The upper metal member 32B includes one or more metal layers. The upper metal member 32B can include a plurality of metal layers formed using different metals as main materials.

A metal such as copper or aluminum is used as the main material of the lower metal member 32C. The lower metal member 32C includes one or more metal layers. The lower metal member 32C can include a plurality of metal layers formed using different metals as main materials.

The wiring layer 33 can be formed using a metal. For example, the wiring layer 33 can be formed using AuSn solder (a metal layer of AuSn).

For example, the length of the short-side direction or the lateral direction of the submount 30 is in a range from 750 μm to 850 μm. In addition, the length of the long-side direction or the longitudinal direction of the submount 30 is in a range from 2000 μm to 2150 μm. In addition, a difference between the length of the submount 30 in the longitudinal direction and the length of the submount 30 in the lateral direction is in a range from 1200 μm to 1400 μm.

For example, the thickness of the submount 30 (the width in a direction perpendicular to the upper surface 31A) is in a range from 250 μm to 350 μm. Also, for example, the thickness of the substrate 32A is in a range from 180 μm to 220 μm. Also, for example, the thickness of the upper metal member 32B is in a range from 35 μm to 65 μm. Also, for example, the thickness of the lower metal member 32C is in a range from 35 μm to 65 μm. Also, for example, the thickness of the wiring layer 33 is in a range from 2 μm to 4 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of the light-reflective surface 41B formed of the main material, a general form of the reflective member 40 may be formed of the main material, and the light-reflective surface 41B may be formed on a surface of the general form. In this case, the light-reflective surface 41B can be formed using, for example, a layer of metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light with which the light-reflective surface 41B is irradiated is equal to or more than 90%. The reflectance may be equal to or more than 95%. The reflectance may be equal to or more than 99%. The light reflectance is equal to or less than 100%, or is less than 100%.

### Protective Element 50

The protective element 50 has an upper surface, a lower surface, and one or more lateral surfaces. The shape of the protective element 50 is a rectangular parallelepiped. The shape of the protective element 50 need not be a rectangular parallelepiped.

The protective element 50 prevents breakage of a specific element (the semiconductor laser element, for example) due to an excessive current flowing through the element. The protective element 50 is, for example, a Zener diode. A Zener diode formed of Si can be used.

### Wiring 60

The wiring 60 is a linear conductive material having bonding portions at both ends. The bonding portions at both ends serve as portions for bonding to other components. The wiring 60 is used for electrical connection between two components. The wiring 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical member 70 may have an optical action surface at a position different from the upper surface 71A, the lower surface 71B, or the lateral surface 71C. For example, the optical action surface may be formed not on a surface of the optical member 70 but on an inner side of the optical member 70.

The optical member 70 can have one or more lens surfaces 71D. The lens surface 71D is the optical action surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. The lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

The outer shape of the optical member 70 in a top view is rectangular. The outer shape of the optical member 70 in a top view need not be rectangular. The lower surface 71B is a flat surface. The lens surface 71D is not formed on the lower surface 71B side of the optical member 70. The shape of the lower surface 71B is rectangular. The shape of the lower surface 71B need not be rectangular.

In the optical member 70, a portion overlapping with the lens surface 71D in a top view is a lens portion 72A. In the optical member 70, a portion overlapping with the upper surface 71A in a top view is a non-lens portion 72B. The lower surface 71B has a region constituting the lower surface of one or each of the lens portions 72A and a region constituting the lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lenses. In the optical member 70 illustrated in the drawing(s), the coupling direction is the same as the X direction.

The plurality of lens surfaces 71D are formed such that the vertices of the respective lens surfaces 71D are provided on one straight line. The virtual straight line connecting the respective vertices is parallel to the lower surface 71B of the optical member 70. The term “parallel” as used here allows for a difference within ±5 degrees.

The curvatures of some or all of the plurality of lens surfaces 71D, that is, two or more lens surfaces 71D can be the same. The plurality of lens surfaces 71D can all have the same curvatures.

The optical member 70 has transmissivity. In the optical member 70, the transmittance with respect to the peak wavelength of light incident on the optical member 70 is equal to or more than 80%. The optical member 70 may include a region having transmissivity and a region having no transmissivity (hereinafter, referred to as a non-light-transmissive region). In the non-light-transmissive region, the transmittance with respect to the peak wavelength of light incident on the optical member 70 is equal to or less than 50%. The optical member 70 can be formed using, for example, glass such as BK7.

### Light-Emitting Device 1

In the light-emitting device 1, the one or more semiconductor laser elements 20 are disposed in the internal space of the package 10. The one or more semiconductor laser elements 20 are disposed on the base 11. The one or more semiconductor laser elements 20 are disposed on the first upper surface 11A.

One or each of the semiconductor laser elements 20 emits light from the light-emitting surface 22 toward a first direction. In the example of the light-emitting device 1 illustrated by the drawing(s), the first direction is the same as the positive direction of Y. The one or more semiconductor laser elements 20 emit red light.

The one or more semiconductor laser elements 20 may include a plurality of the semiconductor laser elements 20 disposed side by side in a second direction. The second direction may be a direction perpendicular to the first direction. In the example of the light-emitting device 1 illustrated by the drawing(s), the second direction is the same as the X direction.

Light that travels in the same direction is emitted from each of the plurality of semiconductor laser elements 20. Light having the same color may be emitted from each of the plurality of semiconductor laser elements 20. The plurality of semiconductor laser elements 20 may constituted by five or more semiconductor laser elements 20. In addition, the plurality of semiconductor laser elements 20 may constituted by five or more, and not more than fifteen, not more than ten, not more than eight, or not more than seven semiconductor laser elements 20.

The one or more semiconductor laser elements 20 may be mounted on the one or more submounts 30. The one or more semiconductor laser elements 20 may be disposed on the base 11 through the one or more submounts 30. The one or each of the semiconductor laser elements 20 is bonded to the wiring layer 33 of the submount 30. Compared to the case in which the semiconductor laser elements 20 are disposed on the base 11 not through the submount 30, disposing the semiconductor laser elements 20 on the base 11 through the submount 30 may improve heat dissipation performance to heat generated from the semiconductor laser elements 20.

In the light-emitting device 1, the one or more reflective members 40 are disposed in the internal space of the package 10. The one or more reflective members 40 are disposed on the base 11. The one or more reflective members 40 are disposed on the first upper surface 11A.

The one or more reflective members 40 are disposed at positions away from the one or more semiconductor laser elements 20 in the first direction. Light emitted from the one or more semiconductor laser elements 20 is reflected by the one or more reflective members 40. The light reflected by the one or more reflective members 40 travels in a third direction. The light that travels in the third direction passes through the package 10 and is emitted to the outside of the package 10. The third direction may be a direction perpendicular to the first direction and the second direction. In the example of the light-emitting device 1 illustrated by the drawing(s), the third direction is the same as the positive direction of Z.

The one or more reflective members 40 may include a plurality of the reflective members 40 disposed side by side in a fourth direction. The fourth direction may be the same as the second direction. Aligning the second direction with the fourth direction can contribute to size reduction of the light-emitting device 1.

The light-reflective surface 41B of one reflective member 40 may correspond to light emitted from one semiconductor laser element 20. The main portion of the light emitted from the one or each of the semiconductor laser elements 20 is reflected by the light-reflective surface 41B of the corresponding reflective member 40. The light-reflective surface 41B of one reflective member 40 may reflect the light emitted from the plurality of semiconductor laser elements 20.

In the light-emitting device 1, the one or more protective elements 50 are disposed in the internal space of the package 10. The one or more protective elements 50 are disposed on the base 11 or on the submount 30. The one or more protective elements 50 are disposed in order to protect the one or more semiconductor laser elements 20. In the light-emitting device 1 illustrated by the drawing(s), the one or more protective elements 50 are disposed on the base 11.

In the light-emitting device 1, the plurality of wirings 60 are provided in order to electrically connect the one or more semiconductor laser elements 20 to the base 11. The plurality of wirings 60 are bonded to the semiconductor laser elements 20, the wiring layer 33 of the submount 30, or the inner wiring portions 12A1 of the base 11. As a result, the one or more semiconductor laser elements 20 electrically connect to the outer wiring portions 12A2 of the base 11.

The one or more semiconductor laser elements 20 include at least one first semiconductor laser element 20A that is a semiconductor laser element 20 electrically connected to the first inner wiring portion 12A11 and the second inner wiring portion 12A12. In the light-emitting device 1 illustrated by the drawing(s), the one or more semiconductor laser elements 20 are all first semiconductor laser elements 20A. The plurality of semiconductor laser elements 20 can be connected in series by the plurality of wirings 60.

The plurality of wirings 60 include a first wiring 60A bonded to the first inner wiring portion 12A11 and electrically connected to the first semiconductor laser element 20A. The plurality of wirings 60 include a second wiring 60B bonded to the second inner wiring portion 12A12 and electrically connected to the first semiconductor laser element 20A.

The first inner wiring portion 12A11, to which the first wiring 60A is bonded, electrically connects to the first semiconductor laser element 20A on the first electrode side. The second inner wiring portion 12A12, to which the second wiring 60B is bonded, electrically connects to the first semiconductor laser element 20A on the second electrode side. The first electrode side means that, in the current path, the first electrode is closer than the second electrode, and the second electrode side means that, in the current path, the second electrode is closer than the first electrode.

The first inner wiring portion 12A11, to which the first wiring 60A is bonded, is the inner wiring portion 12A1 being connected on both sides. The second inner wiring portion 12A12, to which the second wiring 60B is bonded, is the inner wiring portion 12A1 being connected on both sides. One of the first inner wiring portion 12A11 and the second inner wiring portion 12A12 is not necessarily the inner wiring portion 12A1 being connected on both sides. The inner wiring portion 12A1 that is not the inner wiring portion 12A1 being connected on both sides is, in other words, the inner wiring portion 12A1 that satisfies either a condition of not including the first outer wiring portion 12A21 having electrical connection or a condition of not including the second outer wiring portion 12A22 having electrical connection.

In the light-emitting device 1, the optical member 70 is disposed outside the package 10. The optical member 70 is bonded to the package 10. The optical member 70 is bonded to the upper surface 14A of the package 10 with an adhesive interposed between the optical member 70 and the package 10. The optical member 70 is bonded to the lid body 14. A UV-curable or thermosetting resin adhesive may be used as the adhesive.

The light emitted from the package 10 enters the optical member 70. The light having entered the optical member 70 enters an optical action surface, is imparted an optical action, and exits from the optical action surface. For example, light collimated by the lens surface 71D serving as the optical action surface exits from the optical member 70.

One lens surface 71D or one lens portion 72A may correspond to light emitted from one semiconductor laser element 20. The main portion of light emitted from the one or each of the semiconductor laser elements 20 passes through the corresponding lens surface 71D of the lens portion 72A.

### Wiring Substrate 101

The wiring substrate 101 has an upper surface 101A, a lower surface 101B, and one or more lateral surfaces. The wiring substrate 101 has a plate-like shape. The outer edge shape of the wiring substrate 101 in a top view is rectangular. This rectangular shape can be a rectangular shape with long sides and short sides. In the package 10 illustrated by the drawings, a short-side direction of the rectangular shape is the same as the X direction, and a long-side direction is the same as the Y direction.

The wiring substrate 101 includes a heat dissipation portion 101D, a wiring portion 101E, and an insulating portion 101F. The heat dissipation portion 101D serves as a heat dissipation path for heat generated from other components mounted on the wiring substrate 101. The wiring portion 101E electrically connects to other components mounted on the wiring substrate 101.

The insulating portion 101F insulates the heat dissipation portion 101D from the wiring portion 101E. In the wiring substrate 101, the heat dissipation portion 101D and the wiring portion 101E are not electrically connected. In addition, the insulating portion 101F may also be provided to protect a part of the wiring portion 101E from contact with other members.

The wiring substrate 101 includes a bonding portion 101G. The bonding portion 101G is provided to bond to other components in a sufficient state. The sufficient state herein refers to, for example, a state in which sufficient bonding strength is ensured, and also, for example, a state in which sufficient positional accuracy is ensured. The bonding portion 101G is insulated from the heat dissipation portion 101D and the wiring portion 101E by the insulating portion 101F.

Here, on the upper surface 101A of the wiring substrate 101, among the heat dissipation portion 101D, the wiring portion 101E, and the insulating portion 101F, a region of the heat dissipation portion 101D positioned uppermost is defined as the upper surface 101A of the heat dissipation portion 101D, a region of the wiring portion 101E positioned uppermost is defined as the upper surface 101A of the wiring portion 101E, and a region of the insulating portion 101F positioned uppermost is defined as the upper surface 101A of the insulating portion 101F.

In addition, among the heat dissipation portion 101D, the wiring portion 101E, the insulating portion 101F, and the bonding portion 101G on the upper surface 101A of the wiring substrate 101, a region of the bonding portion 101G positioned uppermost is defined as the upper surface 101A of the bonding portion 101G.

The wiring substrate 101 includes a heat dissipation member 111, a plurality of conductive members 121, and one or more insulating members 131. The heat dissipation portion 101D may include the heat dissipation member 111. The wiring portion 101E may include the plurality of conductive members 121. The insulating portion 101F may include the one or more insulating members 131.

The bonding portion 101G may include the plurality of conductive members 121. Both the wiring portion 101E and the bonding portion 101G can include conductive members 121 formed of the same material. Here, a member that constitutes the wiring portion 101E is referred to as a wiring member 121A, and a member that constitutes the bonding portion 101G is referred to as a bonding member 121B. The bonding member 121B may be a member different from the conductive members 121 that constitute the wiring member 121A. The wiring substrate 101 includes a plurality of wiring members 121A.

The wiring substrate 101 is provided with one or more through holes 101H. The one or more through holes 101H include a through hole 101H used for fixing the wiring substrate 101 to another member (component). For example, a screw is fitted into the through hole 101H to fix the wiring substrate 101 to another member. The one or more through holes 101H include the through hole 101H used for determining the positions where the wiring substrate 101 is fixed to another member.

The heat dissipation member 111 has a first upper surface 111A. The heat dissipation member 111 has a second upper surface 111B at a position lower than the first upper surface 111A. The heat dissipation member 111 includes a protrusion protruding from the second upper surface 111B, and the first upper surface 111A can be an upper surface of the protrusion. The height of the protrusion of the heat dissipation member 111 (height from the second upper surface 111B to the first upper surface 111A) is smaller than the height from the lower surface of the heat dissipation member 111 to the second upper surface 111B.

The one or more insulating members 131 are provided on the heat dissipation member 111. The one or more insulating members 131 are provided on the second upper surface 111B. The plurality of conductive members 121 are provided on the second upper surface 111B through the insulating member 131. The plurality of conductive members 121 are disposed apart from each other and are not electrically connected to each other.

The one or more insulating members 131 are provided between the heat dissipation member 111 and each of the conductive members 121. The one or more insulating members 131 are partially provided on the conductive members 121 in a top view. Due to the insulating member 131, one continuous conductive member 121 appears to be visually divided into a plurality of regions. In this manner, a wiring pattern is formed on the upper surface 101A of the wiring substrate 101.

As the main material of the heat dissipation member 111, a metal material can be used. As the main material of the heat dissipation member 111, for example, a single-component metal, such as Cu, Ag, Al, Ni, Rh, Au, Ti, Pt, Pd, Mo, Cr, and W, or an alloy containing any of these metals can be used. The heat dissipation member 111 is preferably formed of a material with a high heat dissipating property. The heat dissipation member 111 can be formed containing copper at 95 mass % or more.

The conductive members 121 may use a metal material as a main material. As the main material of the conductive members 121, for example, a single-component metal, such as Cu, Ag, Al, Ni, Rh, Au, Ti, Pt, Pd, Mo, Cr, and W, or an alloy containing any of these metals can be used.

The insulating member 131 is formed of an insulating material. For example, polyimide can be used as the main material of the insulating member 131. Also, for example, as the main material of the insulating member 131, glass epoxy obtained by impregnating one or more glass cloths with a thermosetting insulating resin, such as an epoxy resin, and curing the thermosetting insulating resin or a liquid crystal polymer can be used. In forming the insulating portion 101F, a plurality of insulating members 131 formed of main materials different from each other may be used. For example, a film-like polyimide may be employed as one of the insulating members 131, and a resist such as a solder resist may be employed as another insulating member 131.

### Connector 201

The connector 201 has an insertion port into which a connector cable is inserted.

### Thermistor 301

The thermistor 301 can be used as an element for measuring temperatures.

Subsequently, the light-emitting module 901 will be described.

### Light-Emitting Module 901

In the light-emitting module 901, the one or more light-emitting devices 1 are mounted on the wiring substrate 101. The lower surfaces 11B of the one or more light-emitting devices 1 are disposed on the upper surface 101A of the wiring substrate 101. The wiring substrate 101 includes the one or more bonding regions 102. The light-emitting device 1 is bonded to the bonding region 102 of the wiring substrate 101.

The bonding region 102 includes the upper surface 101A of the wiring portion 101E. The bonding region 102 includes the upper surface 101A of the bonding portion 101G. The bonding region 102 includes the upper surface 101A of the heat dissipation portion 101D. The bonding region 102 includes the upper surface 101A of the insulating portion 101F. The bonding region 102 may be a smallest rectangular region that includes the light-emitting device 1 and also includes a region of the upper surface 101A of the wiring portion 101E bonded to the light-emitting device 1.

One or each of the light-emitting devices 1 includes one or more outer wiring portions 12A2 bonded to the wiring portion 101E in the bonding region 102. The one or each of the light-emitting devices 1 includes one or more outer wiring portions 12A2 bonded to the bonding portion 101G in the bonding region 102. The base portion 11M is bonded to the heat dissipation portion 101D.

The one or more first outer wiring portions 12A21 are bonded to the wiring substrate 101 in the bonding region 102. The one or more second outer wiring portions 12A22 are bonded to the wiring substrate 101 in the bonding region 102.

Here, the one or more first outer wiring portions 12A21 of the light-emitting device 1 bonded to the wiring substrate 101 in the bonding region 102 are referred to as a first conductive portion 12B1. Further, the one or more second outer wiring portions 12A22 of the light-emitting device 1 bonded to the wiring substrate 101 in the bonding region 102 are referred to as a second conductive portion 12B2.

The first conductive portion 12B1 includes a first conductive region 12B11 and a second conductive region 12B12 that are not electrically connected to each other in the state of the base 11. The second conductive portion 12B2 includes a first conductive region 12B21 and a second conductive region 12B22 that are not electrically connected to each other in the state of the base 11. One conductive region may correspond to one wiring portion 12A.

In addition, the expression “in the state of the base 11” means the state in which a bare base 11, not the state of the base 11 configured as a component of the light-emitting device 1 or the light-emitting module 901. For example, two conductive regions that are not electrically connected to each other in the state of the base 11 can be electrically connected through the semiconductor laser element 20, the submount 30, the wiring 60, and the like in the state of the base 11 configured as a component of the light-emitting device 1.

In the wiring portion 101E of the wiring substrate 101, a first electrode portion 101E1 and a second electrode portion 101E2 for supplying electric power to the one or more semiconductor laser elements 20 are provided. The first electrode portion 101E1 is electrically connected to the first semiconductor laser element 20A on the first electrode side of the first semiconductor laser element 20A. The second electrode portion 101E2 is electrically connected to the first semiconductor laser element 20A on the second electrode side of the first semiconductor laser element 20A.

The plurality of wiring members 121A can be regarded as members for forming a current path (hereinafter referred to as a first current path) from the first electrode portion 101E1 to the second electrode portion 101E2 or from the second electrode portion 101E2 to the first electrode portion 101E1 through the one or more light-emitting devices 1. The first current path may be formed only from the one or more light-emitting devices 1 and the plurality of wiring members 121A, and, for example, may also be formed including other members by connecting the plurality of wiring members 121A with wires.

The first current path is formed in the order of the first electrode portion 101E1, the first conductive portion 12B1, the one or more semiconductor laser elements 20, the second conductive portion 12B2, and the second electrode portion 101E2, or in the reverse order. The one or more semiconductor laser elements 20 can emit light by consuming electric power supplied through the base 11.

The plurality of wiring members 121A include a plurality of wiring regions 122. The plurality of wiring members 121A include the wiring regions 122 connected to the first conductive portion 12B1 within the bonding region 102. The wiring region 122 is connected to the first conductive region 12B11 of the first conductive portion 12B1. The wiring region 122 is not covered with the insulating member 131 in a top view. The wiring region 122 is included in the upper surface 101A of the wiring portion 101E. The plurality of wiring members 121A are not connected to the second conductive region 12B12 of the first conductive portion 12B1.

The plurality of wiring members 121A include wiring regions 122 connected to the second conductive portion 12B2 within the bonding region 102. The wiring region 122 is connected to the first conductive region 12B21 of the second conductive portion 12B2. The wiring region 122 is not covered with the insulating member 131 in a top view. The wiring region 122 is included in the upper surface 101A of the wiring portion 101E. The plurality of wiring members 121A are not connected to the second conductive region 12B22 of the second conductive portion 12B2. Here, the wiring region 122 connected to the first conductive region 12B21 of the second conductive portion 12B2 is referred to as a first wiring region 122A.

The plurality of wiring members 121A include the first wiring region 122A connected to the first conductive region 12B21 of the second conductive portion 12B2 within the bonding region 102, and a second wiring region 122B opposed to the first wiring region 122A with the second conductive region 12B22 of the second conductive portion 12B2 interposed between the first wiring region 122A and the second wiring region 122B in a top view. The first wiring region 122A and the second wiring region 122B constitute a part of the first current path.

The second wiring region 122B is located outside the bonding region 102 of the light-emitting device 1. In addition, the wiring member 121A forming the first current path between the first conductive region 12B21 of the second conductive portion 12B2 and the second wiring region 122B is not in contact with the second conductive region 12B22 of the second conductive portion 12B2. In a case in which the plurality of wiring members 121A form the first current path between the first conductive region 12B21 of the second conductive portion 12B2 and the second wiring region 122B, none of the wiring members 121A is in contact with the second conductive region 12B22 of the second conductive portion 12B2. Accordingly, the first current path can be formed such that a current path is not formed between the first wiring region 122A of the wiring substrate 101 and the second conductive region 12B22 of the light-emitting device 1, and a current path passing through the second conductive region 12B22 of the light-emitting device 1 is not formed between the first wiring region 122A and a wiring region 122 for second external connection.

When the number of current paths passing through inside of the base 11 of the light-emitting device 1 increases, the heat generated in the base 11 increases, and the performance (optical output) of the semiconductor laser element 20 disposed in the package 10 may decrease. Devising the structure of the wiring portion 101E of the wiring substrate 101 and reducing the number of current paths passing through the base 11 can reduce wiring resistance of the light-emitting module 901, and improve performance of the light-emitting module 901.

The plurality of wiring members 121A include a connection region 122C connecting the first wiring region 122A and the second wiring region 122B. In other words, the first wiring region 122A, the second wiring region 122B, and the connection region 122C are regions included in one wiring member 121A, and constituting these regions with one wiring member 121A is efficient in manufacturing. The connection region 122C is not in contact with the second conductive region 12B22 of the second conductive portion 12B2.

The connection region 122C is covered with the insulating member 131 and is not exposed on the upper surface 101A in a top view. In a top view, the upper surface 101A of the wiring substrate 101 overlapping the connection region 122C corresponds to the upper surface 101A of the insulating portion 101F. As a result, contact of the connection region 122C with an exterior of the light-emitting module 901 can be avoided.

The second wiring region 122B is covered with the insulating member 131 and is not exposed on the upper surface 101A in a top view. In a top view, the upper surface 101A of the wiring substrate 101 overlapping the second wiring region 122B corresponds to the upper surface 101A of the insulating portion 101F.

The plurality of wiring members 121A have the bypass region 122D that, in a top view, connects to the second wiring region 122B outside the light-emitting device 1 and the bonding region 102 of the light-emitting device 1, and extends in a direction from the second conductive portion 12B2 toward the first conductive portion 12B1. In a top view, the upper surface 101A of the wiring substrate 101 overlapping the bypass region 122D corresponds to the upper surface 101A of the insulating portion 101F.

Each of the first electrode portion 101E1 and the second electrode portion 101E2 is provided with the wiring region 122 for connecting wirings that are to be electrically connected to an external power source in order to supply electric power to the one or more semiconductor laser elements 20. For example, the wirings that are to be electrically connected to an external power source are bonded to these wiring regions 122, or the connector 201 for inserting the wirings that are to be electrically connected to the external power source are bonded to these wiring regions 122. These wiring regions 122 are referred to as the wiring region 122 for first external connection and the wiring region 122 for second external connection, respectively, and are distinguished from other wiring regions 122.

The wiring region 122 for first external connection is provided in one of two regions into which the upper surface 101A of the wiring substrate 101 is divided by a virtual straight line L1 passing through the light-emitting device 1 and not passing through the first lateral surface or the second lateral surface of the base 11 in a top view. The wiring region 122 for second external connection is provided in one of two regions into which the upper surface 101A of the wiring substrate 101 is divided by a virtual straight line L1 passing through the light-emitting device 1 and not passing through the first lateral surface or the second lateral surface of the base 11 in a top view. These wiring regions 122 are provided close to each other in one region, so that wiring connection can be easily performed.

Both the wiring region 122 for first external connection and the wiring region 122 for second external connection are provided, in a top view, beside the first conductive portion 12B1 of the light-emitting device 1. In a top view, the distance from the first conductive portion 12B1 to the wiring region 122 for first external connection is shorter than the distance from the second conductive portion 12B2 to the wiring region 122 for first external connection.

The wiring region 122 for second external connection is provided at a position apart from the wiring region 122 for first external connection in a fifth direction. The virtual straight line L1 is a line parallel to the fifth direction. In the light-emitting module 901 illustrated by the drawing(s), the fifth direction is the same as the positive direction of Y.

The plurality of wiring members 121A include a first wiring member 121A1 including the wiring region 122 for first external connection and a second wiring member 121A2 including the wiring region 122 for second external connection. The first wiring member 121A1 is included in the first electrode portion 101E1, and the second wiring member 121A2 is included in the second electrode portion 101E2.

In the bonding region 102, the wiring region 122 bonded to the first conductive portion 12B1 is included in the first wiring member 121A1. The wiring region 122 for first external connection and the first conductive portion 12B1 are electrically connected by the first wiring member 121A1.

In the bonding region 102, the wiring region 122 bonded to the second conductive portion 12B2 is included in the second wiring member 121A2. The wiring region 122 for second external connection and the second conductive portion 12B2 are electrically connected by the second wiring member 121A2.

The second wiring member 121A2 includes the second wiring region 122B. The second wiring member 121A2 may include the first wiring region 122A and the connection region 122C. The second wiring member 121A2 may include the bypass region 122D. Constituting the second electrode portion 101E2 with one wiring member 121A including the wiring region 122 for second external connection is efficient in manufacturing.

In a top view, the second conductive region 12B12 of the first conductive portion 12B1 is provided at a position apart from the first conductive region 12B11 of the first conductive portion 12B1 in a sixth direction. In the light-emitting module 901 illustrated by the drawing(s), the sixth direction is the same as the positive direction of Y.

In a top view, the second conductive region 12B22 of the second conductive portion 12B2 is provided at a position apart from the first conductive region 12B21 of the second conductive portion 12B2 in the sixth direction. In a top view, the connection region 122C is provided at a position apart from the second conductive region 12B22 of the second conductive portion 12B2 in a direction perpendicular to the sixth direction.

In a top view, in a direction perpendicular to the sixth direction, the width of the connection region 122C is smaller than the width of the first wiring region 122A. As a result, an increase in size of the wiring substrate 101 or the light-emitting module 901 can be suppressed. In addition, in a top view, in a direction perpendicular to the sixth direction, the width of the connection region 122C is smaller than the width of the second wiring region 122B.

The second conductive region 12B22 of the second conductive portion 12B2 is electrically connected to the first conductive portion 12B1. Thus, in a case in which the second conductive region 12B22 of the second conductive portion 12B2 and the first conductive portion 12B1 are electrically connected, the technical significance increases in devising the structure of the wiring portion 101E in the wiring substrate 101 to reduce current paths passing through the base 11 of the light-emitting device 1.

The second conductive region 12B22 of the second conductive portion 12B2 is electrically connected to the first conductive region 12B11 of the first conductive portion 12B1. In this case, when the wiring member 121A forming the first current path between the first conductive region 12B21 of the second conductive portion 12B2 and the second wiring region 122B comes into contact with the second conductive region 12B22 of the second conductive portion 12B2, the light-emitting device 1 may fail to operate normally.

The first conductive region 12B21 of the second conductive portion 12B2 is electrically connected to the second conductive region 12B12 of the first conductive portion 12B1. The second conductive region 12B12 of the first conductive portion 12B1 is not connected to the wiring portion 101E of the wiring substrate 101. Accordingly, an increase in current paths passing through the base 11 and a failure of the light-emitting device 1 to operate normally can be avoided.

In a state of the base 11, the first inner wiring portion 12A11 to which the first wiring 60A is bonded is electrically connected to the first conductive region 12B11 of the first conductive portion 12B1. In a state of the base 11, the second inner wiring portion 12A12 to which the second wiring 60B is bonded is electrically connected to the first conductive region 12B21 of the second conductive portion 12B2.

The first current path is formed in the order of the wiring region 122 for first external connection, the first conductive region 12B11 of the first conductive portion 12B1, the first inner wiring portion 12A11 to which the first wiring 60A is bonded, the one or more semiconductor laser elements 20, the second inner wiring portion 12A12 to which the second wiring 60B is bonded, the first conductive region 12B21 of the second conductive portion 12B2, and the wiring region 122 for second external connection, or in the reverse order.

The second conductive region 12B12 of the first conductive portion 12B1 is bonded to the bonding portion 101G of the wiring substrate 101. The second conductive region 12B12 of the first conductive portion 12B1 does not substantially serve as a wiring that constitutes a part of the current path. Bonding the second conductive region 12B12 of the first conductive portion 12B1 to the bonding portion 101G stabilizes mounting of the light-emitting device 1 on the wiring substrate 101, and can improve mounting accuracy.

The second conductive region 12B22 of the second conductive portion 12B2 is bonded to the bonding portion 101G of a wiring substrate 101. The second conductive region 12B22 of the second conductive portion 12B2 does not substantially serve as a wiring that constitutes a part of the current path. Bonding the second conductive region 12B22 of the second conductive portion 12B2 to the bonding portion 101G stabilizes mounting of the light-emitting device 1 on the wiring substrate 101, and can improve mounting accuracy.

In the light-emitting module 901 of the first embodiment, among the first conductive region 12B11 of the first conductive portion 12B1, the second conductive region 12B12 of the first conductive portion 12B1, the first conductive region 12B21 of the second conductive portion 12B2, and the second conductive region 12B22 of the second conductive portion 12B2, the regions that substantially serve to form the first current path are the first conductive region 12B11 of the first conductive portion 12B1 and the first conductive region 12B21 of the second conductive portion 12B2, while the second conductive region 12B12 of the first conductive portion 12B1 and the second conductive region 12B22 of the second conductive portion 12B2 do not substantially serve to form the first current path.

In the light-emitting module 901, the connector 201 is mounted on the wiring substrate 101. The connector 201 is connected to the wiring portion 101E. The connector 201 is connected to the wiring region 122 for first external connection and the wiring region 122 for second external connection. The connector 201 is provided, through which power supply to the light-emitting device 1 is easily performed.

In the light-emitting module 901, the thermistor 301 is mounted on the wiring substrate 101. The thermistor 301 is connected to the wiring portion 101E. The thermistor 301 is electrically connected to the connector 201. The thermistor 301 is provided, by which the temperature of the light-emitting device 1 can be detected.

### Second Embodiment

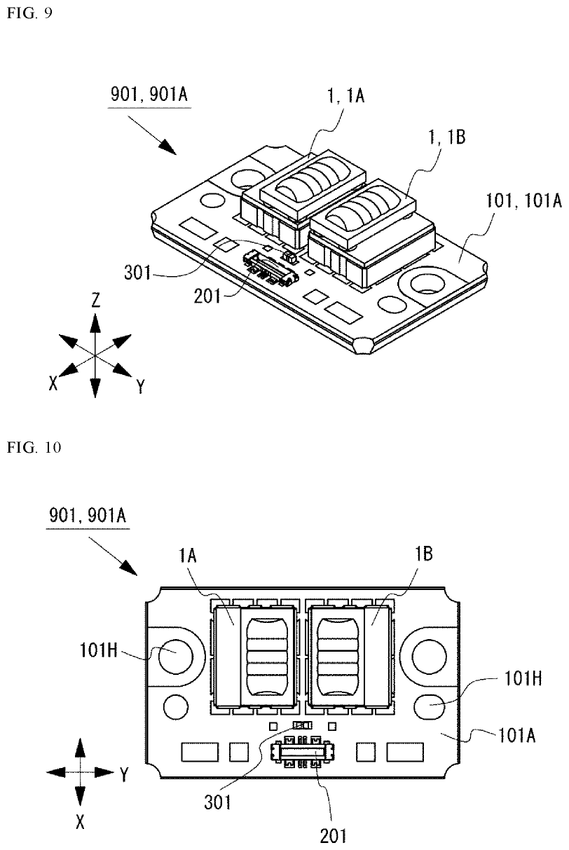

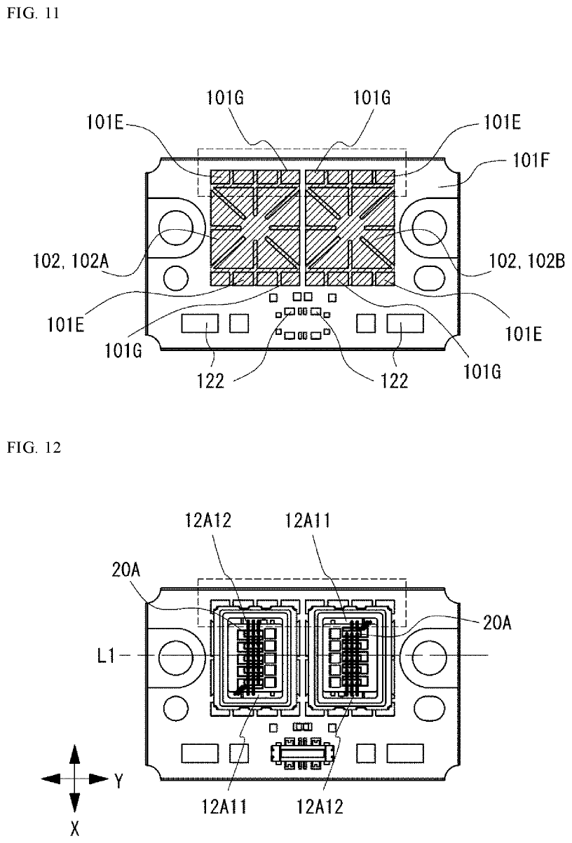

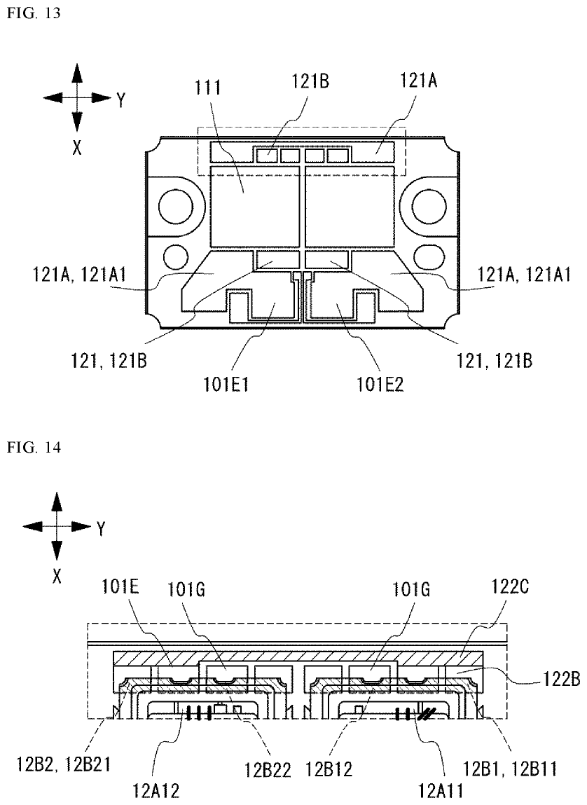

A light-emitting module 901 according to a second embodiment will be described. FIGS. 5A to 5M and FIGS. 9 to 14 are drawings for describing an exemplary embodiment of the light-emitting module 901 of the second embodiment. FIGS. 5A to 5M are the same drawings as those described in the first embodiment. FIG. 9 is a schematic perspective view of the light-emitting module 901. A light-emitting device 1 aligned with the X direction, the Y direction, and the Z direction of the light-emitting module 901 is a first light-emitting device 1A. FIG. 10 is a schematic top view of the light-emitting module 901. FIG. 11 is a schematic top view of a wiring substrate 101. In FIG. 11, hatching is added to a bonding region 102. FIG. 12 is a schematic top view illustrating the inside of a package 10 of the light-emitting device 1 in the light-emitting module 901. FIG. 13 is a schematic top view of the wiring substrate 101 with an insulating portion 101F removed. FIG. 14 is a schematic enlarged top view for describing a connection state between the light-emitting device 1 and the wiring substrate 101 in the light-emitting module 901. FIG. 14 enlarges a region surrounded by a broken-line rectangle in FIGS. 11 to 13. In addition, for clearly illustrating the connection state, some components are appropriately made transparent or omitted.

All of the contents related to the light-emitting module 901 and the respective components in the first embodiment described above, except for contents that can be said to be inconsistent with the drawings of FIGS. 5A to 5M and FIGS. 9 to 14 related to the light-emitting module 901 of the second embodiment, are also applicable as descriptions of the light-emitting module 901 of the second embodiment. All the consistent contents will not be repeated here in order to avoid redundancy.

### Light-Emitting Module 901

The light-emitting module 901 in the first embodiment illustrates an example in which one light-emitting device 1 is mounted on the wiring substrate 101, and the description of the technology has been made based on this example (what is disclosed by the light-emitting module 901 in the first embodiment is not limited to the illustrated example). The light-emitting module 901 in the second embodiment is described by illustrating an example in which two light-emitting devices 1 are mounted on the wiring substrate 101.

In the light-emitting module 901, two light-emitting devices 1 are mounted on the wiring substrate 101. The wiring substrate 101 has two bonding regions 102. Here, the respective light-emitting devices 1 are referred to as a first light-emitting device 1A and a second light-emitting device 1B, and the respective bonding regions 102 are referred to as a first bonding region 102A and a second bonding region 102B.

Identical bases 11 may be used for the first light-emitting device 1A and the second light-emitting device 1B. At least the bases 11 having the same number and positions of wiring portions 12A, and having the same electrical connection relationship between the inner wiring portions 12A1 and the outer wiring portions 12A2 may be used, and the expression “identical bases 11” herein means that the bases 11 at least satisfy these conditions. The condition that satisfies the “identical bases 11” may additionally include a condition that the wiring portions 12A on the bases 11 have the same shape. Alternatively, the condition that satisfies the “identical bases 11” may additionally include a condition that the outer edge shape in a top view is the same. Furthermore, the condition that satisfies the “identical bases 11” may additionally include a condition that the overall outer shape is the same.

The second bonding region 102B is disposed apart from the first bonding region 102A. The first light-emitting device 1A is bonded to the first bonding region 102A of the wiring substrate 101, and the second light-emitting device 1B is bonded to the second bonding region 102B of the wiring substrate 101.

The first light-emitting device 1A and the second light-emitting device 1B are disposed on the upper surface 101A of the wiring substrate 101 so as to face each other in a top view. The direction from a first conductive portion 12B1 toward a second conductive portion 12B2 of the first light-emitting device 1A, and the direction from the second conductive portion 12B2 toward the first conductive portion 12B1 of the second light-emitting device 1B are the same direction. A first direction in the first light-emitting device 1A is the direction toward the second light-emitting device 1B, and the first direction in the second light-emitting device 1B is the direction toward the first light-emitting device 1A.

A first electrode portion 101E1 of the wiring substrate 101 is electrically connected to a first semiconductor laser element 20A of the first light-emitting device 1A and a first semiconductor laser element 20A of the second light-emitting device 1B on the first electrode side of these first semiconductor laser elements 20A. A second electrode portion 101E2 is electrically connected to a first semiconductor laser element 20A of the first light-emitting device 1A and a first semiconductor laser element 20A of the second light-emitting device 1B on the second electrode side of these first semiconductor laser elements 20A.

Here, for convenience, the current path in the light-emitting module 901 of the second embodiment is referred to as a second current path, and as described above, contents of descriptions of the first current path that are consistent with descriptions of the second current path apply also to the second current path.

The second current path is formed in the order of the first electrode portion 101E1, the first conductive portion 12B1 of the first light-emitting device 1A, one or more semiconductor laser elements 20 of the first light-emitting device 1A, the second conductive portion 12B2 of the first light-emitting device 1A, the first conductive portion 12B1 of the second light-emitting device 1B, one or more semiconductor laser elements 20 of the second light-emitting device 1B, the second conductive portion 12B2 of the second light-emitting device 1B, and the second electrode portion 101E2, or in the reverse order.

A plurality of wiring members 121A include a first wiring region 122A connected to a first conductive region 12B21 of the second conductive portion 12B2 of the first light-emitting device 1A within the first bonding region 102A, and a second wiring region 122B opposed to the first wiring region 122A, with a second conductive region 12B22 of the second conductive portion 12B2 of the first light-emitting device 1A interposed between the first wiring region 122A and the second wiring region 122B in a top view. The second wiring region 122B is in the second bonding region 102B.

The second wiring region 122B is connected, within the second bonding region 102B, to the first conductive portion 12B1 of the second light-emitting device 1B. The second wiring region 122B is connected to a first conductive region 12B11 of the first conductive portion 12B1 of the second light-emitting device 1B. The second wiring region 122B is not covered with an insulating member 131 in a top view.

The wiring member 121A forming the first current path between the first conductive region 12B21 of the second conductive portion 12B2 of the first light-emitting device 1A and the second wiring region 122B is not in contact with the second conductive region 12B22 of the second conductive portion 12B2 of the first light-emitting device 1A or the second conductive region 12B12 of the first conductive portion 12B1 of the second light-emitting device 1B. A connection region 122C is not in contact with the second conductive region 12B22 of the second conductive portion 12B2 of the first light-emitting device 1A or the second conductive region 12B12 of the first conductive portion 12B1 of the second light-emitting device 1B.

Both the wiring region 122 for first external connection and the wiring region 122 for second external connection are provided beside the first conductive portion 12B1 of the first light-emitting device 1A and beside the second conductive portion 12B2 of the second light-emitting device 1B in a top view.

Within the first bonding region 102A, the wiring region 122 that is bonded to the first conductive portion 12B1 is included in a first wiring member 121A1. Within the second bonding region 102B, the wiring region 122 that is bonded to the second conductive portion 12B2 is included in a second wiring member 121A2. The second wiring member 121A2 does not include the second wiring region 122B.

In the second light-emitting device 1B, a second conductive region 12B12 of the first conductive portion 12B1 is provided at a position that is apart from the first conductive region 12B11 of the first conductive portion 12B1 in a direction opposite to the sixth direction in a top view. The second conductive region 12B22 of the second conductive portion 12B2 is provided at a position apart from the first conductive region 12B21 of the second conductive portion 12B2 in a direction opposite to the sixth direction in a top view.

The connection region 122C is provided at a position apart from the second conductive region 12B22 of the second conductive portion 12B2 of the first light-emitting device 1A and the second conductive region 12B12 of the first conductive portion 12B1 of the second light-emitting device 1B in a direction perpendicular to the sixth direction in a top view.

The second conductive region 12B12 of the first conductive portion 12B1 of the first light-emitting device 1A, and the second conductive region 12B22 of the second conductive portion 12B2 of the second light-emitting device 1B are not connected to a wiring portion 101E of the wiring substrate 101.

In the light-emitting module 901 of the second embodiment illustrated in the drawing(s), even when the connection region 122C is replaced with an insulating member to electrically insulate the first wiring region 122A from the second wiring region 122B, and a bonding portion 101G that is bonded to the second conductive region 12B12 of the first conductive portion 12B1 of the first light-emitting device 1A and the bonding portion 101G that is bonded to the second conductive region 12B22 of the second conductive portion 12B2 of the second light-emitting device 1B are constituted by the single wiring member 121A, the current path of the light-emitting module 901 can still be formed. However, in this case, the number of current paths passing through the first light-emitting device 1A and the number of current paths passing through the second light-emitting device 1B are increased. The light-emitting module 901 of the second embodiment can improve the light output.

Here, based on the light-emitting modules 901 of the first embodiment and the second embodiment described above, the disclosed technical contents are organized. While the light-emitting function of the light-emitting device 1 is desired for a device mounted on the wiring substrate 101, as long as the device exhibits the desired function, the device mounted on the wiring substrate 101 is not limited to the light-emitting device 1. However, when there is a relationship in which performance of the function exhibited by the device is improved by devising the wiring substrate 101, the device mounted on the wiring substrate 101 is a device including at least a power-consuming component that consumes electric power and thus exhibits the function. Accordingly, the semiconductor laser element 20 can be regarded as an example of the power-consuming component. Also, when performance of the function is improved by a principle in which heat generated in the device is reduced by devising the wiring substrate 101, it should be the power-consuming component whose performance of the function to be exhibited is affected by the temperature. Accordingly, electronic components including many semiconductor elements can be an example of the power-consuming component. The light-emitting device 1 and the light-emitting module 901 are also names corresponding to the semiconductor laser element that is an example of the power-consuming component, and in view of the relationship with the disclosed technical contents, limitation to the function or use of “light-emitting” is not essential. By referring solely to a device or module without characters “light-emitting”, the disclosed technical contents are defined as not limiting the use to “light-emitting”, but as being applicable to devices or modules in general that include a power-consuming component.

### Third Embodiment

A plurality of light-emitting modules 901 according to a third embodiment will be described. The plurality of light-emitting modules 901 are manufactured or managed by the same entity at the same time. The entity is, for example, a natural person or a legal person. More specific examples include a manufacturer that manufactures the plurality of light-emitting modules 901, a seller that sells the plurality of light-emitting modules 901, and a seller that sells a product including the plurality of light-emitting modules 901 mounted therein.

The plurality of light-emitting modules 901 include a first light-emitting module 901A and a second light-emitting module 901B. At the same time, a seller that sells a product including the second light-emitting module 901B mounted therein, separately from a product including the first light-emitting module 901A mounted therein also falls under the “seller that sells a product including the plurality of light-emitting modules 901 mounted therein” described above. For example, when a lineup of these light-emitting-module-mounted products is held at the same time and preparation has been made to provide these products for sale to purchasers, the products can be regarded as being managed by the same entity at the same time.

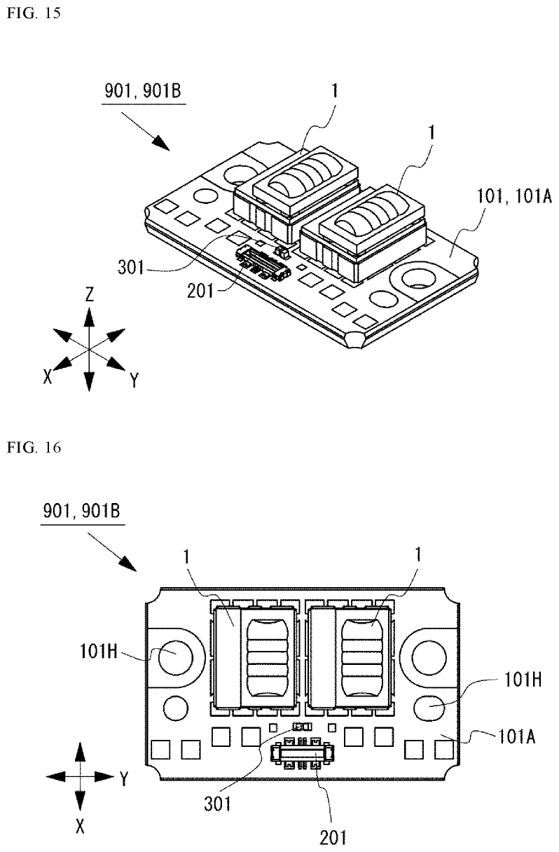

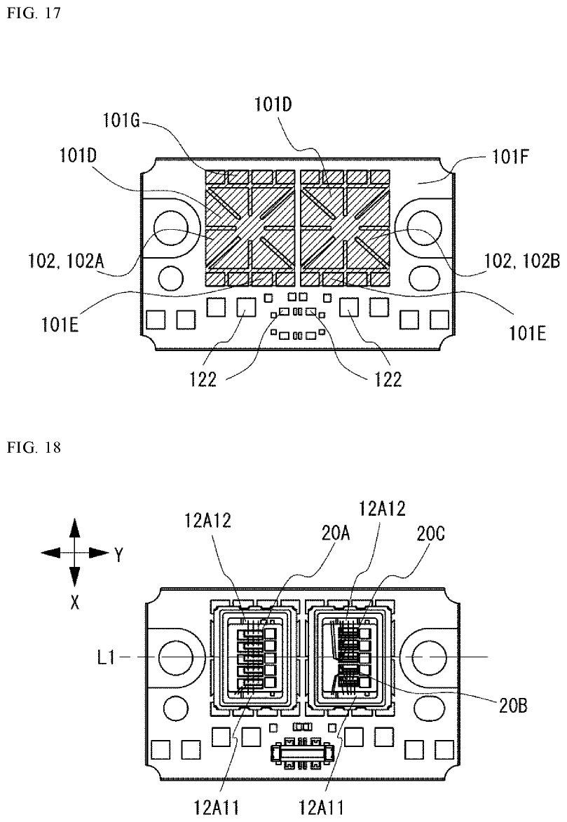

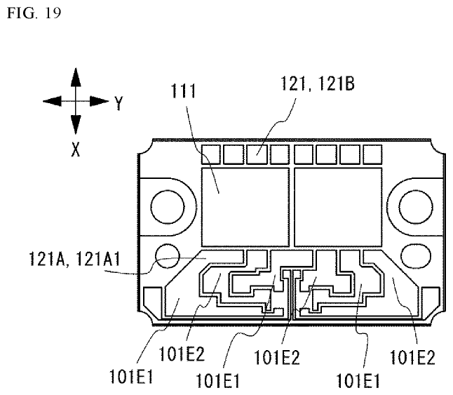

The first light-emitting module 901A is the light-emitting module 901 of the first embodiment or the light-emitting module 901 of the second embodiment. FIGS. 5A to 5M and FIGS. 15 to 19 are drawings for describing an exemplary embodiment of the second light-emitting module 901B. FIGS. 5A to 5M are the same drawings as those described in the first embodiment. FIG. 15 is a schematic perspective view of the second light-emitting module 901B. FIG. 16 is a schematic top view of the second light-emitting module 901B. FIG. 17 is a schematic top view of a wiring substrate 101. In FIG. 17, hatching is added to a bonding region 102. FIG. 18 is a schematic top view illustrating the inside of a package 10 of a light-emitting device 1 in the second light-emitting module 901B. FIG. 19 is a schematic top view of the wiring substrate 101 with an insulating portion 101F not shown.

All of the descriptions related to the light-emitting module 901 and the respective components in the first embodiment and the second embodiment described above, except for the contents that can be said to be inconsistent with the drawings of FIGS. 5A to 5M and FIGS. 15 to 19 related to the second light-emitting module 901B, are also applicable to the description of the second light-emitting module 901B. All the consistent contents will not be repeated here in order to avoid redundancy.

### Second Light-Emitting Module 901B

In the second light-emitting module 901B, the light-emitting device 1 in which only one of a first conductive portion 12B1 and a second conductive portion 12B2 is used for forming a current path for supplying electric power to a semiconductor laser element 20 is mounted on the wiring substrate 101. In particular, the light-emitting device 1 in which only the conductive portion closer to a wiring region 122 for external connection is used can be mounted.

A conceivable reason why only one of the conductive portions is used for supplying electric power to the semiconductor laser element 20 included in the light-emitting device 1 is, for example, to avoid an increase in size of the wiring substrate 101. Shortening the current path passing through the light-emitting device 1 leads to a situation in which the current path is compensated by components outside the light-emitting device 1, mainly by the wiring substrate 101. The base 11 includes the inner wiring portions 12A1 being connected on both sides, so that while using a first inner wiring portion 12A11 and a second inner wiring portion 12A12 in formation of a current path, selection can be appropriately made as to whether either a first conductive portion 12B1 or a second conductive portion 12B2 is used or both are used, and the light-emitting device 1 can have selectivity in usage modes.

For example, as the second light-emitting module 901B illustrated by the drawing(s), the two light-emitting devices 1 are mounted on the wiring substrate 101, and one of the light-emitting devices 1 is the same as the light-emitting device 1 in the light-emitting module 901 exemplified in the first embodiment and the second embodiment, and a current path from a first electrode portion 101E1 to a second electrode portion 101E2, or from the second electrode portion 101E2 to the first electrode portion 101E1, is formed through the light-emitting device 1.

However, this current path is formed in the order of the first electrode portion 101E1, a first conductive region 12B11 of the first conductive portion 12B1, one or more semiconductor laser elements 20, a second conductive region 12B12 of the first conductive portion 12B1, and the second electrode portion 101E2, or in the reverse order. In the second light-emitting module 901B, formation of a current path for the one or more semiconductor laser elements 20 included in the one of the light-emitting devices 1 does not need the second conductive portion 12B2.

Thus, the base 11 has selectivity of a wiring portion 12A to be used for formation of a current path, so that the light-emitting module 901 suitable for a specific usage mode can be provided by using the wiring substrate 101 corresponding to the usage mode for the light-emitting device 1 having selectivity in the usage mode.

In the second light-emitting module 901B, one of the two light-emitting devices 1 is bonded to a first bonding region 102A of the wiring substrate 101, and the other light-emitting device 1 is bonded to a second bonding region 102B.

A plurality of wiring members 121A include a wiring member 121A connected to the first conductive region 12B11 of the first conductive portion 12B1 within the first bonding region 102A, and the wiring member 121A connected to the second conductive region 12B12 of the first conductive portion 12B1 within the first bonding region 102A. Of these two wiring members 121A, the former wiring member 121A can be a first wiring member 121A1, and the latter wiring member 121A can be a second wiring member 121A2.

In the second light-emitting module 901B, the two light-emitting devices 1 are arranged in the same orientation. A first direction of one of the light-emitting devices 1 and the first direction of the other light-emitting device 1 are the same direction.

In the other light-emitting device 1, two sets of the one or more semiconductor laser elements 20 connected in series are arranged on the base 11. A first set of the one or more semiconductor laser elements 20 are electrically connected to two first inner wiring portions 12A11, and a second set of the one or more semiconductor laser elements 20 are electrically connected to two second inner wiring portions 12A12.

The one or more semiconductor laser elements 20 included in the other light-emitting device 1 include at least one second semiconductor laser element 20B that is a semiconductor laser element 20 electrically connected to the two first inner wiring portions 12A11. All of the first set of the one or more semiconductor laser elements 20 are the second semiconductor laser elements 20B. The second semiconductor laser elements 20B are not electrically connected to the second inner wiring portion 12A12.

The one or more semiconductor laser elements 20 included in the other light-emitting device 1 include at least one third semiconductor laser element 20C that is a semiconductor laser element 20 electrically connected to two second inner wiring portions 12A12. All of the second set of the one or more semiconductor laser elements 20 are the third semiconductor laser elements 20C. The third semiconductor laser elements 20C are not electrically connected to the first inner wiring portion 12A11.

The plurality of wiring members 121A include a wiring member 121A connected to the first conductive region 12B11 of the first conductive portion 12B1 within the second bonding region 102B, and a wiring member 121A connected to the second conductive region 12B12 of the first conductive portion 12B1 within the second bonding region 102B. The two wiring members 121A are electrically connected to the two first inner wiring portions 12A11 to which the first set of the one or more semiconductor laser elements 20 are electrically connected.

On the wiring substrate 101, the first electrode portion 101E1 and the second electrode portion 101E2 for supplying electric power to the first set of the one or more semiconductor laser elements 20 are provided. As a result, through the other light-emitting device 1, a current path for the first set of the one or more semiconductor laser elements 20 is formed from the first electrode portion 101E1 to the second electrode portion 101E2 or from the second electrode portion 101E2 to the first electrode portion 101E1.

The other light-emitting device 1 includes a third conductive region 12B13 and a fourth conductive region 12B14 in the first conductive portion 12B1 that are not electrically connected to each other in a state of the base 11. The third conductive region 12B13 and the fourth conductive region 12B14 are not electrically connected to the first conductive region 12B11 or the second conductive region 12B12.

The plurality of wiring members 121A include the wiring member 121A connected to the third conductive region 12B13 of the first conductive portion 12B1 within the second bonding region 102B, and the wiring member 121A connected to the fourth conductive region 12B14 of the first conductive portion 12B1 within the second bonding region 102B. The two wiring members 121A are electrically connected to the two first inner wiring portions 12A11 to which the second set of the one or more semiconductor laser elements 20 are electrically connected.

On the wiring substrate 101, the first electrode portion 101E1 and the second electrode portion 101E2 for supplying electric power to the second set of the one or more semiconductor laser elements 20 are provided. As a result, through the other light-emitting device 1, a current path for the second set of the one or more semiconductor laser elements 20 is formed from the first electrode portion 101E1 to the second electrode portion 101E2 or from the second electrode portion 101E2 to the first electrode portion 101E1.

The base 11 may include a third conductive region 12B23 and a fourth conductive region 12B24 in the second conductive portion 12B2 that are not electrically connected to each other in a state of the base 11. The third conductive region 12B23 and the fourth conductive region 12B24 are not electrically connected to a first conductive region 12B21 or a second conductive region 12B22. As a result, even when the two light-emitting devices 1 are disposed to face each other as in the second embodiment, the same current path or a similar current path can be formed without the need for the first conductive portion 12B1. For both the light-emitting device 1 mounted on the first light-emitting module 901A and the light-emitting device 1 mounted on the second light-emitting module 901B, identical bases 11 can be used.

For example, the first light-emitting module 901A emits light of one color, and the second light-emitting module 901B emits light of three colors, red, green, and blue.

Although each of the embodiments according to the present disclosure has been described above, the module according to the present disclosure is not strictly limited to the light-emitting module in each of the embodiments. In other words, the present disclosure can be implemented without being limited to an outer shape or a structure of the light-emitting module disclosed by each of the embodiments. The present disclosure can be applied without the need to include all the components. For example, in a case in which some of the components of the module disclosed by the embodiments are not stated in the scope of the claims, the degree of freedom in design by those skilled in the art for the partial components, including substitutions, omissions, modifications of shapes, and changes of materials, is permitted, and based on that, the disclosure stated in the scope of the claims is specified as being applied.

The module described in the embodiments can be used for a projector. That is, the projector can be said to be one of the modes of usage to which the present disclosure is applied. The present disclosure is not limited thereto, and can be used in various modes of usage, such as lighting, exposure, on-vehicle headlights, and backlights of head-mounted displays and other displays.

### REFERENCE SIGNS LIST

1 Light-emitting device
1A First light-emitting device
1B Second light-emitting device
10 Package
11 Base
11A First upper surface
11B Lower surface
11C Second upper surface
11D Outer lateral surface
11E Inner lateral surface
11F Step portion
   11F1 First step portion
   11F2 Second step portion
   11G Upper surface
   11H Lateral surface
11M Base portion
11N Frame portion
12A Wiring portion
   12A1 Inner wiring portion
      12A11 First inner wiring portion
      12A12 Second inner wiring portion
   12A2 Outer wiring portion
      12A21 First outer wiring portion
   12B1 First conductive portion
      12B11 First conductive region
      12B12 Second conductive region
      12B13 Third conductive region
      12B14 Fourth conductive region
   12A22 Second outer wiring portion
      12B2 Second conductive portion
         12B21 First conductive region
         12B22 Second conductive region
         12B23 Third conductive region
         12B24 Fourth conductive region
13A Bonding pattern
14 Lid body
14A Upper surface
14B Lower surface
14C Lateral surface
20 Semiconductor laser element
20A First semiconductor laser element
20B Second semiconductor laser element
20C Third semiconductor laser element
21A Upper surface
21B Lower surface
21C Lateral surface
22 Light-emitting surface
30 Submount
31A Upper surface
31B Lower surface
31C Lateral surface
32A Substrate
32B Upper metal member
32C Lower metal member
33 Wiring layer
40 Reflective member
41A Lower surface
41B Light-reflective surface
50 Protective element
60 Wiring
60A First wiring
60B Second wiring
70 Optical member (lens member)
71A Upper surface
71B Lower surface
71C Lateral surface
71D Lens surface (optical action surface)
72A Lens portion
72B Non-lens portion
101 Wiring substrate
101A Upper surface
101B Lower surface
101D Heat dissipation portion
101E Wiring portion
101E1 First electrode portion
101E2 Second electrode portion
101F Insulating portion
101G Bonding portion
101H Through hole
102 Bonding region
102A First bonding region
102B Second bonding region
111 Heat dissipation member
111A First upper surface
111B Second upper surface
111E Lower surface
121 Conductive member
121A Wiring member
121A1 First wiring member
121A2 Second wiring member
121B Bonding member
122 Wiring region
122A First wiring region
122B Second wiring region
122C Connection region
122D Bypass region
131 Insulating member
201 Connector
301 Thermistor
901 Light-emitting module
901A First light-emitting module
901B Second light-emitting module

What is claimed is:

1. A first module comprising:
a first device comprising,
a first base comprising an upper surface, a lower surface, and a first conductive portion and a second conductive portion that are provided on the lower surface, and
a first power-consuming component disposed on the first base, and configured to consume electric power supplied through the first base; and
a first wiring substrate provided with a first electrode portion and a second electrode portion for supplying electric power to the first power-consuming component, the first wiring substrate comprising a plurality of wiring members for forming a first current path from the first electrode portion to the second electrode portion or from the second electrode portion to the first electrode portion through the first device, wherein
the first power-consuming component comprises a first electrode and a second electrode,
the first electrode portion is electrically connected to the first power-consuming component on a first electrode side of the first power-consuming component,
the second electrode portion is electrically connected to the first power-consuming component on a second electrode side of the first power-consuming component,
the first conductive portion and the second conductive portion of the first device are bonded to the first wiring substrate in a first bonding region of the first wiring substrate,
the second conductive portion of the first device comprises a first conductive region and a second conductive region that are not electrically connected to each other in a state of the first base,
the plurality of wiring members of the first wiring substrate comprise a first wiring region connected to the first conductive region of the second conductive portion in the first bonding region, and a second wiring region opposed to the first wiring region with the second conductive region of the second conductive portion interposed between the first wiring region and the second wiring region in a top view,
the second wiring region of the first wiring substrate is located outside the first bonding region,
the first wiring region and the second wiring region form a part of the first current path, and
the wiring member forming the first current path between the first conductive region of the second conductive portion and the second wiring region is not in contact with the second conductive region of the second conductive portion.

2. The first module according to claim 1,
wherein the plurality of wiring members of the first wiring substrate include a connection region connecting the first wiring region and the second wiring region.

3. The first module according to claim 2,
wherein the second conductive region of the second conductive portion is provided at a position apart from the first conductive region of the second conductive portion in a first direction in a top view, and
the connection region is provided at a position apart from the second conductive region of the second conductive portion in a direction perpendicular to the first direction in a top view.

4. The first module according to claim 2,
wherein the first wiring substrate comprises an insulating member, and the connection region is covered with the insulating member and not exposed on the upper surface in a top view.

5. The first module according to claim 1,
wherein the first base has a first outer lateral surface and a second outer lateral surface, the second outer lateral surface being an outer lateral surface on an opposite side to the first outer lateral surface,
the first conductive portion is provided on a first outer lateral surface side,
the second conductive portion is provided on a second outer lateral surface side,
the first electrode portion is provided with a wiring region for first external connection for connecting a wiring to be electrically connected to an external power source to supply electric power to the first power-consuming component,
the second electrode portion is provided with a wiring region for second external connection for connecting a wiring to be electrically connected to an external power source to supply electric power to the first power-consuming component, and
the wiring region for first external connection is provided, in a top view, in one of two regions into which an upper surface of the first wiring substrate is divided by a virtual straight line passing through the first device and not passing through the first outer lateral surface or the second outer lateral surface of the first base, and
the wiring region for second external connection is provided, in a top view, in one of two regions into which an upper surface of the first wiring substrate is divided by a virtual straight line passing through the first device and not passing through the first outer lateral surface or the second outer lateral surface of the first base.

6. The first module according to claim 1,
wherein, in the first base, the second conductive region of the second conductive portion is electrically connected to the first conductive portion.

7. The first module according to claim 6,
wherein the first conductive portion comprises a first conductive region and a second conductive region that are not electrically connected to each other in a state of the first base,
the first conductive region of the second conductive portion is electrically connected to the second conductive region of the first conductive portion, and
the second conductive region of the second conductive portion is electrically connected to the first conductive region of the first conductive portion.

8. The first module according to claim 7,
wherein, in a top view, the second conductive region of the first conductive portion is provided at a position apart from the first conductive region of the first conductive portion in a first direction.

9. The first module according to claim 5,
wherein the plurality of wiring members comprise a first wiring member comprising the wiring region for first external connection, and a second wiring member comprising the wiring region for second external connection, and
the second wiring member comprises the second wiring region.

10. The first module according to claim 5, wherein
the plurality of wiring members comprise a first wiring member comprising the wiring region for first external connection, and a second wiring member comprising the wiring region for second external connection, the first module further comprises a second device comprising,
a second base comprising an upper surface, a lower surface, and a first conductive portion and a second conductive portion that are provided on the lower surface, and
a second power-consuming component disposed on the upper surface of the second base, and configured to consume electric power supplied through the second base,
the first conductive portion and the second conductive portion of the second device are bonded to the first wiring substrate in a second bonding region of the first wiring substrate apart from the first bonding region,
the second wiring region is located in the second bonding region, and
the second wiring member does not comprise the second wiring region.

11. The first module according to claim 10,
wherein the first base and the second base are identical bases.

12. A plurality of modules comprising:
the first module according to claim 1; and
a second module comprising:
a third device comprising,
a third base comprising an upper surface, a lower surface, and a first conductive portion and a second conductive portion that are provided on the lower surface, and
a third power-consuming component disposed on the upper surface of the third base, and configured to consume electric power supplied through the third base; and
a second wiring substrate provided with a first electrode portion and a second electrode portion for supplying electric power to the third power-consuming component, the second wiring substrate comprising a plurality of wiring members for forming a second current path from the first electrode portion to the second electrode portion or from the second electrode portion to the first electrode portion through the third device, wherein
the first base and the third base are identical bases,
the first conductive portion and the second conductive portion of the third device are bonded to the second wiring substrate in a bonding region of the second wiring substrate,
the first conductive portion of the third base comprises a first conductive region and a second conductive region that are not electrically connected to each other,
the second conductive portion of the third base comprises a first conductive region and a second conductive region that are not electrically connected to each other,
the plurality of wiring members of the second wiring substrate comprise a first wiring member connected to the first conductive region of the first conductive portion in the bonding region of the second wiring substrate, and a second wiring member connected to the second conductive region of the first conductive portion in the bonding region of the second wiring substrate, and
formation of the second current path does not need the second conductive portion of the third device.
